(19) United States
(12) Patent Application Publication
(10) Pub. No.: US 2022/0013741 A1
(43) Pub. Date: Jan. 13, 2022

(54) METHOD FOR PRODUCING ORGANIC PHOTOELECTRIC CONVERSION ELEMENT

(71) Applicant: SUMITOMO CHEMICAL COMPANY, LIMITED, Tokyo (JP)

(72) Inventors: Daisuke INOKUCHI, Osaka-shi (JP); Takefumi KAWATA, Osaka-shi (JP)

(73) Assignee: SUMITOMO CHEMICAL COMPANY, LIMITED, Tokyo (JP)

(21) Appl. No.: 17/296,209

(22) PCT Filed: Nov. 19, 2019
(86) PCT No.: PCT/JP2019/045196

§ 371 Date: May 21, 2021

(30) Foreign Application Priority Data
Nov. 26, 2018 (JP) 2018-220335

(51) Int. Cl. H01L 51/44; H01L 51/00

(52) U.S. Cl. CPC H01L 51/442; H01L 51/0043; H01L 51/448

(57) ABSTRACT

The present invention enables on-demand production of an organic photoelectric conversion element regardless of the timing of material synthesis. Provided is a method for producing an organic photoelectric conversion element that comprises a pair of electrodes including an anode and a cathode, and an active layer that is provided between the pair of electrodes and includes a π-conjugated polymer, said method including a storing step of storing the π-conjugated polymer in an enclosure container which has an atmosphere therein that suppresses increase in the electron spin concentration of the π-conjugated polymer, and a step of forming the active layer using the π-conjugated polymer after storage.

### TECHNICAL FIELD

The present invention relates to a method for producing an organic photoelectric conversion element, and further relates to a method for storing an organic semiconductor material used for the production method, and a reagent package that can be used for the production method and the storage method.

### BACKGROUND ART

An organic photoelectric conversion element is an extremely useful device from the standpoint of, for example, energy saving and reduction in carbon dioxide emissions, and has been attracting attention.

An organic photoelectric conversion element is an electronic element that comprises at least a pair of electrodes including an anode and a cathode, and an active layer that is disposed between the pair of electrodes and includes an organic semiconductor material. In the organic photoelectric conversion element, any one of the electrodes is formed of an optically transparent material, and the active layer is irradiated with light incident from the side of the electrode having optical transparency. Then, electric charges (hole and electron) are generated in the active layer by the energy of the light (hν) incident on the active layer, and the generated hole moves toward an anode and the generated electron moves toward a cathode. The electric charges that have arrived at the anode and cathode are taken out of the organic photoelectric conversion element.

It is known that long term storage of organic semiconductor materials that are used as functional materials of the active layer of an organic photoelectric conversion element is difficult especially under the air atmosphere. For example, the following Patent Document 1 discloses that, with respect to storage of materials of an organic layer of an organic electroluminescent element (organic luminescent materials), the organic luminescent materials should be accommodated in a light-resistant container immediately after the synthesis of the organic luminescent materials, the storage temperature should be regulated within a range of −100° C. to 100° C., and the organic luminescent materials should be stored under an inert gas atmosphere (e.g., nitrogen, carbon dioxide, or argon atmosphere).

### PRIOR ART DOCUMENT

### Patent Document

Patent Document 1: JP-A-2009-027091

### SUMMARY OF THE INVENTION

### Problems to be Solved by the Invention

However, the mechanisms of deterioration of organic semiconductor materials, which results in not only deterioration of physical properties of the organic semiconductor materials but also deterioration of electrical characteristics of an organic photoelectric conversion element produced by using the organic semiconductor material, is not necessarily clear. Thus, conventionally, in order to totally avoid a plurality of factors that may be associated with the deterioration of organic semiconductor materials, storage methods that require complicated processing and large-scale facilities, as disclosed in the above-described Patent Document 1, are unavoidable.

In addition, since long-term storage of organic semiconductor materials is not recommended under the present circumstances, when organic semiconductor materials are manufactured, the period of storing the manufactured organic semiconductor materials should be as short as possible to produce devices using the organic semiconductor materials. Thus, it is required that the timing of the production of the devices is adjusted so as to be immediately after the manufacture of the organic semiconductor materials.

Thus, there is a strong need for a technique that realizes further long-term storage of organic semiconductor materials.

### Means for Solving the Problems

The present inventors have made extensive investigations to solve the above-described problems and have found that, in time-dependent deterioration of organic semiconductor materials, there is a correlation between electron spin concentration of an organic semiconductor material and atmospheric oxygen concentration during storage, and thereby have made the present invention.

The present invention provides the following [1] to [20].

[1] A method for producing an organic photoelectric conversion element that comprises a pair of electrodes including an anode and a cathode, and an active layer that is disposed between the pair of electrodes and includes a π-conjugated polymer, the method comprising:
a storing step of storing the π-conjugated polymer in an enclosure container which has an atmosphere therein that suppresses increase in the electron spin concentration of the π-conjugated polymer; and
a step of forming the active layer using the π-conjugated polymer after storage.
[2] The method for producing an organic photoelectric conversion element according to [1], wherein the atmosphere in the storing step is an atmosphere having an oxygen concentration of 1% or less.
[3] The method for producing an organic photoelectric conversion element according to [1] or [2], wherein, in the storing step, an oxygen absorber is provided in the enclosure container.
[4] The method for producing an organic photoelectric conversion element according to any one of [1] to [3], wherein the π-conjugated polymer after storage has an electron spin concentration of 10×10¹⁶ or less per gram.
[5] The method for producing an organic photoelectric conversion element according to any one of [1] to [4], wherein the π-conjugated polymer after storage has a maximum absorption wavelength of 500 nm or more.
[6] The method for producing an organic photoelectric conversion element according to any one of [1] to [5], wherein the electron spin concentration of the π-conjugated polymer per gram after storage is less than 2.4 times as much as the electron spin concentration of the π-conjugated polymer per gram before storage.
[7] The method for producing an organic photoelectric conversion element according to any one of [1] to [6], further comprising:
a preparation step of preparing an application liquid containing the π-conjugated polymer after storage, wherein the step of forming the active layer is a step of forming the active layer by applying the application liquid obtained in the preparation step.
[8] A reagent package containing:
a π-conjugated polymer for forming an active layer of an organic photoelectric conversion element;
an enclosure container enclosing the π-conjugated polymer in an airtight state, in which the enclosure container has gas barrier properties and the π-conjugated polymer can be enclosed in and taken out of the enclosure container; and an oxygen absorber that is provided so as to come into contact with the atmosphere in the enclosure container in an airtight state, wherein the atmosphere is an atmosphere having an oxygen concentration of 1% or less.
[9] The reagent package according to [8], wherein the π-conjugated polymer after storage has an electron spin concentration of 10×10¹⁶ or less per gram.
[10] The reagent package according to [8] or [9], wherein the π-conjugated polymer after storage has a maximum absorption wavelength of 500 nm or more.
[11] The reagent package according to any one of [8] to [10], wherein the oxygen absorber contains at least one material selected from the group consisting of iron, a sugar, and a reductone.
[12] The reagent package according to [11], wherein the material is a material containing iron.
[13] The reagent package according to any one of [8] to [12], wherein the enclosure container comprises:
a body part that has an opening and accommodates the π-conjugated polymer;
an inner lid that is detachably attached and fitted to an inner wall of the opening, has a recessed portion on which the oxygen absorber is capable of being mounted apart from the π-conjugated polymer, and has a perforation through which the oxygen absorber and the atmosphere in contact with the π-conjugated polymer are capable of coming into contact with each other; and
an outer lid that is detachably attached and fitted to an outer wall of the opening in a state where the inner lid is attached to make the space in the body part into an airtight state.
[14] A storage method comprising a storing step of storing a π-conjugated polymer in an enclosure container which has an atmosphere therein that suppresses increase in the electron spin concentration of the π-conjugated polymer.
[15] The storage method according to [14], wherein the atmosphere in the storing step is an atmosphere having an oxygen concentration of 1% or less.
[16] The storage method according to [14] or [15], wherein the π-conjugated polymer is a π-conjugated polymer that has an electron spin concentration of 10×10¹⁶ or less per gram after storage.
[17] The storage method according to any one of [14] to [16], wherein the π-conjugated polymer has a maximum absorption wavelength of 500 nm or more after storage.
[18] The storage method according to any one of [14] to [17], wherein the oxygen absorber contains at least one material selected from the group consisting of iron, a sugar, and a reductone.
[19] The storage method according to [18], wherein the material contains iron.
[20] The storage method according to any one of [14] to [19], wherein the enclosure container comprises:
a body part that has an opening and accommodates the π-conjugated polymer;
an inner lid that is detachably attached and fitted to an inner wall of the opening, has a recessed portion on which the oxygen absorber is capable of being mounted apart from the π-conjugated polymer, and has a perforation through which the oxygen absorber and the atmosphere in contact with the π-conjugated polymer are capable of coming into contact with each other; and
an outer lid that is detachably attached and fitted to an outer wall of the opening in a state where the inner lid is attached to make the space in the body part into an airtight state.

### Effect of the Invention

According to the present invention, an organic photoelectric conversion element can be produced independent of the timing of synthesis of a π-conjugated polymer as a raw material of an active layer, and therefore on-demand production of the organic photoelectric conversion element using a stored π-conjugated polymer becomes possible.

### BRIEF DESCRIPTION OF THE DRAWINGS

FIG. 1 is a perspective view schematically showing a reagent package.

### MODE FOR CARRYING OUT THE INVENTION

An embodiment of the present invention will be described with reference to drawings below. The drawings are merely rough sketches in terms of the shapes, sizes, and layouts of constituents for the purpose of understanding the present invention. The present invention is not limited by the following descriptions, and modifications of each constituent are possible without departing from the scope of the present invention. In the drawings, similar constituents will be denoted by the same sign, and repeated descriptions may be sometimes eliminated from the following description. The constituents in the embodiment of the present invention are not necessarily used in the layouts in examples shown in the drawings.

### 1. Method for Producing Organic Photoelectric Conversion Element and Method for Storing π-Conjugated Polymer

A method for producing an organic photoelectric conversion element according to the present embodiment is a method for producing an organic photoelectric conversion element that comprises a pair of electrodes including an anode and a cathode, and an active layer that is disposed between the pair of electrodes and includes a π-conjugated polymer, the method comprising: a storing step of storing the above-described π-conjugated polymer in an enclosure container which has an atmosphere therein that suppresses increase in the electron spin concentration of the above-described π-conjugated polymer (hereinafter, referred to as step (1)), and a step of forming an active layer using the above-described π-conjugated polymer after storage (hereinafter, referred to as step (2)).

The method for producing an organic photoelectric conversion element according to the present embodiment includes a method for storing a π-conjugated polymer. The method for storing a π-conjugated polymer includes the above-described step (1).

The organic photoelectric conversion element according to the present embodiment can be produced by suitably combining materials that are selected for forming constituents of the element with an appropriate forming method. The method for producing an organic photoelectric conversion element and the method for storing a π-conjugated polymer according to the present embodiment are described in detail below.

### <Step (1)>

### (i) Enclosure Container

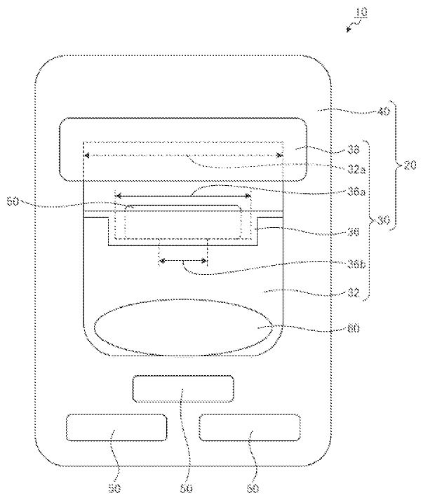

As shown in FIG. 1, an enclosure container 20 is an enclosure container having gas barrier properties, in which a π-conjugated polymer 60 can be enclosed in and taken out of the enclosure container 20 as desired, and the π-conjugated polymer 60 can be enclosed in the enclosure container 20 in an airtight state.

The shape and capacity of the enclosure container 20 are not particularly limited as long as a desired amount of the π-conjugated polymer 60 can be accommodated in and taken out of the enclosure container 20. The enclosure container 20 is not particularly limited as long as the enclosure container 20 can maintain its internal atmosphere in an airtight state, and the atmospheric composition in the enclosure container 20 in an airtight state can be controlled such that the atmosphere in the enclosure container can suppress time-dependent increase in the electron spin concentration of the π-conjugated polymer 60, or, in particular, the oxygen concentration of the atmosphere in the enclosure container 20 can be reduced to a predetermined concentration, and the state in which the oxygen concentration is reduced can be maintained.

Examples of the enclosure container 20 include a bag-shaped container 40, a bottle-shaped container 30 such as a reagent bottle or a reagent container, and combinations thereof, which satisfy the above-described requirements.

The materials constituting the enclosure container 20 are not particularly limited as long as the objects and effects of the present invention are not compromised. Examples of the materials include resin materials such as polyethylene and polyethylene terephthalate, ceramics, glass, metals such as alloys, and combinations thereof.

Specific preferred examples of the enclosure container 20 include a bag-shaped packaging material formed of a bag-shaped aluminum foil having an opening and a fastener designed to open and close the opening as desired; a re-sealable aluminum bag that is a bag-shaped packaging material formed of a polymer film, in which the surface of the polymer film is coated with a metal such as aluminum, or metallic foil such as aluminum foil is laminated to the surface of the polymer film, and the bag-shaped packaging material has an opening and an opening and closing means for opening and closing the opening as desired (e.g., aluminum-type Lamizip (registered trademark) manufactured by SEISANNIPPONSHA LTD.); and a plastic reagent bottle (e.g., CLEAN bottle (trade name) manufactured by AICELLO CORPORATION).

A plurality of types of enclosure containers 20 or a plurality of enclosure containers 20 selected from the enclosure containers 20 exemplified above may be used in combination. In this case, only one of the plurality of types of or plurality of the enclosure containers 20 may be equipped with an oxygen absorber 50, or two or more of the selected enclosure containers 20 or all enclosure containers 20 each may be equipped with an oxygen absorber 50.

Specifically, as shown in FIG. 1, examples of the embodiment include a constitution in which a plastic reagent bottle enclosing an oxygen absorber 50 together with a π-conjugated polymer 60 is further enclosed in a bag-shaped container 40 accommodating one or more oxygen absorbers (packages) (described later).

As described above, when a plurality of or a plurality of types of enclosure containers are used in combination, the lowered oxygen concentration of the atmosphere in contact with a π-conjugated polymer can be further effectively maintained. As a result, deterioration of the π-conjugated polymer can be further effectively prevented.

Alternatively, the enclosure container 20 exemplified above may be used in combination with, for example, a container that is not capable of enclosing an oxygen absorber 50 therein, or a container having an insufficient gas barrier properties or an insufficient airtightness (called a non-hermetic container). In this case, for example, the non-hermetic container may accommodate only a π-conjugated polymer 60, and the non-hermetic container containing the π-conjugated polymer only may be enclosed in the enclosure container 20 exemplified above together with an oxygen absorber 50.

Specifically, examples of the embodiment include a constitution in which a reagent bottle as a non-hermetic container accommodating a π-conjugated polymer 60 is enclosed in a bag-shaped container 40 as an enclosure container 20 together with an oxygen absorber 50. In this case, the non-hermetic container is enclosed such that the non-hermetic container can have an atmosphere therein that suppresses increase in the electron spin concentration of the π-conjugated polymer 60. Accordingly, the enclosure container 20 can also have an atmosphere therein that suppresses increase in the electron spin concentration of the π-conjugated polymer 60, and the π-conjugated polymer 60 can be stored.

Examples of the enclosure container 20 according the present embodiment may include a bottle-shaped container 30 having a constitution, for arranging the π-conjugated polymer 60 and the oxygen absorber 50 apart from each other during storage of the π-conjugated polymer 60, including: a body part 32 that has an opening 32a and accommodates the π-conjugated polymer 60; an inner lid 36 that is detachably attached and fitted to an inner wall of the body part 32, has a recessed portion 36a on which the oxygen absorber 50 is capable of being mounted apart from the π-conjugated polymer 60, and has a perforation 36b through which the oxygen absorber 50 and the atmosphere in contact with the π-conjugated polymer 60 are capable of coming into contact with each other; and an outer lid 38 that is detachably attached and fitted to an outer wall of the opening 32a in a state where the inner lid 36 is attached to make the space in the body part 32 into an airtight state.

Specific examples the constitution include a plastic reagent bottle (bottle-shaped container 30) including an inner lid 36 on which an oxygen absorber 50 is capable of being mounted and an outer lid 38, in which the inner lid 36 has one or more through-holes (perforations 36b) each having a size (diameter) to prevent the oxygen absorber 50 from dropping into the body part 32 that accommodates a π-conjugated polymer 60.

### (ii) Oxygen Absorber

An oxygen absorber 50 according to the present embodiment is arranged, in an enclosure container 20 that accommodates a π-conjugated polymer 60 and is in an airtight state, so as to be in contact with the atmosphere in the enclosure container 20, has a function to make the enclosure container 20 have an atmosphere therein that suppresses increase in the electron spin concentration of the π-conjugated polymer, or, specifically, has a function to make the enclosure container 20 have an atmosphere therein having an oxygen concentration of 1% or less.

Shapes and active ingredients of the oxygen absorber 50 according to the present embodiment are not particularly limited. Examples of the shape of the oxygen absorber 50 include preparations having various shapes such as a tablet, and a sachet type package in which an active ingredient is packaged in a form that allows the active ingredient to perform its function.

Shapes, active ingredients, amounts, or the like of the oxygen absorber 50 can be suitably selected in consideration of a selected form of the enclosure container 20, a type, properties, and an amount of the π-conjugated polymer 60, volume of the atmosphere in the enclosure container 20, an assumed storage period, and the like.

Examples of the active ingredient of the oxygen absorber 50 according to the present embodiment include, from the viewpoint of, in particular, making the atmosphere be an atmosphere having an oxygen concentration of 1% or less and maintaining the oxygen concentration of 1% or less at least for a predetermined time, iron (iron powder), sugars (e.g., glucose and maltooligosaccharide), and organic compounds such as reductones.

The oxygen absorber 50 preferably contains, from the viewpoint of availability and controlling the oxygen concentration in the enclosure container 20, at least one material selected from the group consisting of iron, sugars, and reductones, and, from the viewpoint of adsorbing oxidizing substances other than oxygen in the air, more preferably iron.

Forms of the oxygen absorber 50 are preferably, from the viewpoint of availability, powder and granules, and, from the viewpoint of controlling the oxygen concentration in the enclosure container 20, more preferably powder.

Examples of the oxygen absorber 50 according to the present embodiment include commercially available sachet type packages AGELESS (registered trademark, manufactured by MITSUBISHI GAS CHEMICAL COMPANY, INC.), SequL (registered trademark, manufactured by NISSO FINE CO., LTD.), and WonderKeep (registered trademark, manufactured by Powdertech Co., Ltd.).

The amount of the oxygen absorber 50 (active ingredient) used may be determined in consideration of a type, properties, and an amount of the π-conjugated polymer 60, volume of the atmosphere in the enclosure container 20, an assumed storage period, and the like.

For example, when the volume of the atmosphere in the enclosure container 20 is 50 mL and the assumed storage period is 1 year, it is sufficient that one pack of an oxygen absorber 50 that can absorb 50 mL of oxygen per pack is used.

The manner of disposing an oxygen absorber 50 in an enclosure container 20 is not particularly limited as long as the above-described conditions are satisfied. When a sachet type package is used as an oxygen absorber 50, the package may be disposed so as to be directly in contact with a π-conjugated polymer 60 in the enclosure container 20, or may be disposed so as to be at least in contact with the atmosphere in the enclosure container 20, or, in other words, may be disposed such that the conjugated polymer 60 and the package are apart from each other, and both the conjugated polymer 60 and the package are in contact with the atmosphere in the enclosure container 20.

(iii) π-Conjugated Polymer

Next, a π-conjugated polymer 60 according to the present embodiment is described. The π-conjugated polymer 60 according to the present embodiment is a π-conjugated polymer that can function as a p-type semiconductor material for forming an active layer of an organic photoelectric conversion element.

The π-conjugated polymer 60 according to the present embodiment is a polymer compound having a molecular weight distribution, and having a π-conjugated system formed by alternate repeats of a multiple bond and a single bond that are each constituted by a carbon-carbon bond or a carbon-heteroatom bond in a main chain.

The π-conjugated polymer 60 may be any type of copolymer. For example, the π-conjugated polymer 60 may be any of a block copolymer, a random copolymer, an alternating copolymer, a graft copolymer, and the like.

The π-conjugated polymer 60 according to the present embodiment has a certain weight-average molecular weight versus polystyrene standards.

The weight-average molecular weight versus polystyrene standards refers to a weight-average molecular weight as measured using gel permeation chromatography (GPC) and calculated using polystyrene reference standards.

The weight-average molecular weight versus polystyrene standards of the π-conjugated polymer 60 according to the present embodiment is not particularly limited. In particular, from the viewpoint of efficient preservability, the π-conjugated polymer used has a weight-average molecular weight versus polystyrene standards of preferably 40,000 or more and 200,000 or less, more preferably 40,000 or more and 150,000 or less, and still more preferably 45,000 or more and 150,000 or less.

The method for producing an organic photoelectric conversion element and the method for storing the element according to the present embodiment can be suitably applied to a π-conjugated polymer 60 having an electron spin concentration per gram of 0.3×10¹⁶ (spin/g) or more before storage using the storage method according to the present embodiment (before storage process).

Among π-conjugated polymers 60, it is thought that a π-conjugated polymer 60 having a high electron spin concentration is particularly susceptible to oxygen in storage atmosphere and readily deteriorated (radicalized). Thus, the method for producing an organic photoelectric conversion element, the reagent package 10, and the storage method according to the present invention can be suitably applied to such a π-conjugated polymer having a high electron spin concentration.

The π-conjugated polymer 60 before the storage process according to the present embodiment preferably has an electron spin concentration per gram of 0.3×10¹⁶ (spin/g) or more as described above. From the viewpoint of further effectively suppressing the increase in electron spin concentration, that is, the deterioration of the π-conjugated polymer 60, the π-conjugated polymer 60 more preferably has an electron spin concentration of 0.8×10¹⁶ or more, still more preferably 1.0×10¹⁶ or more, and even more preferably 2.0×10¹⁶ or more. From the viewpoint of external quantum yield, the π-conjugated polymer 60 preferably has an electron spin concentration of 10×10¹⁶ or less, and more preferably 7.0×10¹⁶ or less.

The π-conjugated polymer 60 after storage obtained through the above-described step (1) more preferably has an electron spin concentration per gram of, from the viewpoint of membrane properties of an active layer membrane, 10.0×10¹⁶ or less, still more preferably 8.0×10¹⁶ or less, and even more preferably 7.0×10¹⁶ or less.

The π-conjugated polymer 60 after storage obtained through the above-described step (1) preferably has an electron spin concentration per gram of, from the viewpoint of element properties, less than 2.4 times as much as the electron spin concentration per gram of the π-conjugated polymer 60 before the storage process, more preferably 2.0 times or less, still more preferably 1.5 times or less, and even more preferably 1.3 times or less.

The electron spin concentration refers to a parameter that can be obtained based on an election spin resonance (ESR) spectrum measured by an ESR method. The ESR spectrum can be obtained using, for example, an X-band ESR measurement system.

Specifically, first, an ESR spectrum reflecting characteristics of electron spins of a π-conjugated polymer 60 as a target for the measurement is obtained by an ESR method using an ESR measurement system. Since the area of an ESR spectrum has a correlation with the amount of electron spins, the amount of electron spin can be calculated from the area of the ESR spectrum.

The area of an ESR spectrum can be calculated by any suitable hitherto known calculation methods, or using a commercially available software.

As the method for calculating the amount of electron spins from the area of an ESR spectrum, any suitable hitherto known methods can be used. Examples of the method of calculating the amount of electron spins from the area of an ESR spectrum include a method described in a guidebook entitled “Jitsuyo ESR Nyumon” (An Introduction to Practical ESR) (Kodansha Scientific, Ltd.).

The electron spin concentration (spin/g) can be calculated by dividing the calculated amount of electron spins by the weight of a π-conjugated polymer 60 as a target for the measurement.

The method for producing an organic photoelectric conversion element, the reagent package 10, and the storage method according to the present embodiment can be suitably applied to a π-conjugated polymer 60 having a maximum absorption wavelength of 500 nm or more before and after storage, in other words, a π-conjugated polymer 60 having a maximum absorption wavelength within a wavelength range including the near-infrared region. In the present embodiment, the maximum absorption wavelength is more preferably 600 nm or more, still more preferably 670 nm or more, even more preferably 700 nm or more, and particularly preferably 750 nm or more. On the other hand, the maximum absorption wavelength is more preferably, from the viewpoint of stability of the polymer in the air, 2000 nm or less, and still more preferably 1800 nm or less.

Furthermore, the method for producing an organic photoelectric conversion element, the reagent package 10, and the storage method of the present invention can be suitably applied to a π-conjugated polymer having a difference between the energy level of the lowest unoccupied molecular orbital (LUMO) and the energy level of the highest occupied molecular orbital (HOMO), that is, a band gap of 2.0 eV or less. In the present embodiment, the band gap of a π-conjugated polymer is more preferably 1.8 eV or less, still more preferably 1.6 eV or less, and even more preferably 1.4 eV or less.

For more specific description of the π-conjugated polymer 60 according to the present embodiment, commonly used terms are described below.

Herein, a “constitutional unit” refers to a unit structure that is present in the π-conjugated polymer 60, and the π-conjugated polymer 60 contains at least one unit structure. The “constitutional unit” is preferably contained as “repeating units” (two or more unit structures present in the π-conjugated polymer 60).

A “hydrogen atom” may be a light hydrogen atom or a deuterium atom.

“Halogen atoms” include a fluorine atom, a chlorine atom, a bromine atom, and an iodine atom.

The term “optionally substituted” refers to both a case in which all hydrogen atoms that constitute a compound or group are unsubstituted, and a case in which a part or all of the one or more hydrogen atoms are substituted with a substituent.

An “alkyl group” may be any of linear, branched, and cyclic, unless otherwise indicated. The linear alkyl group generally has, excluding carbon atoms of its substituents, 1 to 50 carbon atoms, preferably 1 to 30 carbon atoms, and more preferably 1 to 20 carbon atoms. The branched or cyclic alkyl group generally has, excluding carbon atoms of its substituents, 3 to 50 carbon atoms, preferably 3 to 30 carbon atoms, and more preferably 4 to 20 carbon atoms.

The alkyl group may have a substituent. Specific examples of the alkyl group include alkyl groups such as a methyl group, an ethyl group, a n-propyl group, an isopropyl group, a n-butyl group, an isobutyl group, a tert-butyl group, a n-pentyl group, an isoamyl group, a 2-ethylbutyl group, a n-hexyl group, a cyclohexyl group, a n-heptyl group, a cyclohexylmethyl group, a cyclohexylethyl group, a n-octyl group, a 2-ethylhexyl group, a 3-n-propylheptyl group, an adamantyl group, a n-decyl group, a 3,7-dimethyloctyl group, a 2-ethyloctyl group, a 2-n-hexyl-decyl group, a n-dodecyl group, a tetradecyl group, a hexadecyl group, an octadecyl group, and an eicosyl group; and alkyl groups each having a substituent, such as a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di-n-hexylphenyl)propyl group, and a 6-ethyloxyhexyl group.

An “aryl group” refers to an atomic group that remains after elimination of one hydrogen atom directly linked to a carbon atom that constitutes a ring of an optionally substituted aromatic hydrocarbon from the optionally substituted aromatic hydrocarbon.

The aryl group may have a substituent. Specific examples of the aryl group include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, and a 4-phenylphenyl group; and a group having a substituent such as an alkyl group, an alkoxy group, an aryl group, or a fluorine atom.

An “alkoxy group” may be any of linear, branched, and cyclic. The linear alkoxy group generally has, excluding carbon atoms of its substituents, 1 to 40 carbon atoms, and preferably 1 to 10 carbon atoms. The branched or cyclic alkoxy group generally has, excluding carbon atoms of its substituents, 3 to 40 carbon atoms, and preferably 4 to 10 carbon atoms.

The alkoxy group may have a substituent. Specific examples of the alkoxy group include a methoxy group, an ethoxy group, a n-propyloxy group, an isopropyloxy group, a n-butyloxy group, an isobutyloxy group, a tert-butyloxy group, a n-pentyloxy group, a n-hexyloxy group, a cyclohexyloxy group, a n-heptyloxy group, a n-octyloxy group, a 2-ethylhexyloxy group, a n-nonyloxy group, a n-decyloxy group, a 3,7-dimethyloctyloxy group, and a lauryloxy group.

An “aryloxy group” generally has, excluding carbon atoms of its substituents, 6 to 60 carbon atoms, and preferably 6 to 48 carbon atoms.

The aryloxy group may have a substituent. Specific examples of the aryloxy group include a phenoxy group, a 1-naphthyloxy group, a 2-naphthyloxy group, a 1-anthracenyloxy group, a 9-anthracenyloxy group, and a 1-pyrenyloxy group; and a group having a substituent such as an alkyl group, an alkoxy group, or a fluorine atom.

An “alkylthio group” may be any of linear, branched, and cyclic. The linear alkylthio group generally has, excluding carbon atoms of its substituents, 1 to 40 carbon atoms, and preferably 1 to 10 carbon atoms. The branched and cyclic alkylthio groups each generally have, excluding carbon atoms of their substituents, 3 to 40 carbon atoms, and preferably 4 to 10 carbon atoms.

The alkylthio group may have a substituent. Specific examples of the alkylthio group include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group, and a trifluoromethylthio group.

The “arylthio group” generally has, excluding carbon atoms of its substituents, 6 to 60 carbon atoms, and preferably 6 to 48 carbon atoms.

The arylthio group may have a substituent. Examples of the arylthio group include a phenylthio group, a C1-C12 alkyloxyphenylthio group (The term “C1-C12” represents that a group that is written directly after “C1-C12” has 1 to 12 carbon atoms. The same applies hereinafter.), a C1-C12 alkylphenylthio group, a 1-naphthylthio group, a 2-naphthylthio group, and a pentafluorophenylthio group.

A “p-valent heterocyclic group” (p represents an integer of 1 or more.) refers to an atomic group that remains after elimination of p hydrogen atoms in hydrogen atoms directly linked to carbon atoms or heteroatoms that constitute a ring of an optionally substituted heterocyclic compound from the optionally substituted heterocyclic compound. Among “p-valent heterocyclic groups”, a “p-valent aromatic heterocyclic group” is preferred. The “p-valent aromatic heterocyclic group” refers to an atomic group that remains after elimination of p hydrogen atoms in hydrogen atoms directly linked to carbon atoms or heteroatoms that constitute a ring of an optionally substituted aromatic heterocyclic compound from the optionally substituted aromatic heterocyclic compound.

Examples of the substituent that the heterocyclic compound may have include a halogen atom, an alkyl group, an aryl group, an alkoxy group, an aryloxy group, an alkylthio group, an arylthio group, a monovalent heterocyclic group, a substituted amino group, an acyl group, an imine residue, an amide group, an acid imide group, a substituted oxycarbonyl group, an alkenyl group, an alkynyl group, a cyano group, and a nitro group.

The aromatic heterocyclic compounds include a compound in which an aromatic ring is fused with a heterocyclic ring that is not aromatic, in addition to a compound in which a heterocyclic ring is aromatic in itself.

Among the aromatic heterocyclic compounds, specific examples of the compound in which a heterocyclic ring is aromatic in itself include oxadiazole, thiadiazole, thiazole, oxazole, thiophene, pyrrole, phosphole, furan, pyridine, pyrazine, pyrimidine, triazine, pyridazine, quinoline, isoquinoline, carbazole, and dibenzophosphole.

Among the aromatic heterocyclic compounds, specific examples of the compound in which an aromatic ring is fused with a heterocyclic ring that is not aromatic include phenoxazine, phenothiazine, dibenzoborole, dibenzosilole, and benzopyran.

The monovalent heterocyclic group generally has, excluding carbon atoms of its substituents, 2 to 60 carbon atoms, and preferably 4 to 20 carbon atoms.

The monovalent heterocyclic group may have a substituent. Specific examples of the monovalent heterocyclic group include a thienyl group, a pyrrolyl group, a furyl group, a pyridyl group, a piperidyl group, a quinolyl group, an isoquinolyl group, a pyrimidinyl group, and a triazinyl group; and substituted forms of the foregoing groups each having a substituent such as an alkyl group or an alkoxy group.

A “substituted amino group” refers to an amino group having a substituent. Examples of the substituent that the substituted amino group may have include an alkyl group, an aryl group, and a monovalent heterocyclic group. The substituent is preferably an alkyl group, an aryl group, and a monovalent heterocyclic group. The substituted amino group generally has 2 to 30 carbon atoms.

Examples of the substituted amino group include dialkylamino groups such as a dimethylamino group and a diethylamino group; and diarylamino groups such as a diphenylamino group, a bis(4-methylphenyl)amino group, a bis(4-tert-butylphenyl)amino group, and a bis(3,5-di-tert-butylphenyl)amino group.

An “acyl group” generally has 2 to 20 carbon atoms, and preferably 2 to 18 carbon atoms. Specific examples of the acyl group include an acetyl group, a propionyl group, a butyryl group, an isobutyryl group, a pivaloyl group, a benzoyl group, a trifluoroacetyl group, and a pentafluorobenzoyl group.

An “imine residue” refers to an atomic group that remains after elimination of one hydrogen atom directly linked to a carbon atom or a nitrogen atom that forms a carbon-nitrogen double bond of an imine compound from the imine compound. The “imine compound” refers to an organic compound that has a carbon-nitrogen double bond in the molecule. Examples of the imine compound include aldimines, ketimines, and a compound in which a hydrogen atom linked to a nitrogen atom that forms a carbon-nitrogen double bond in an aldimine is substituted with an alkyl group or the like.

The imine residue generally has 2 to 20 carbon atoms, and preferably 2 to 18 carbon atoms. Examples of the imine residue include groups represented by the following structural formulae.

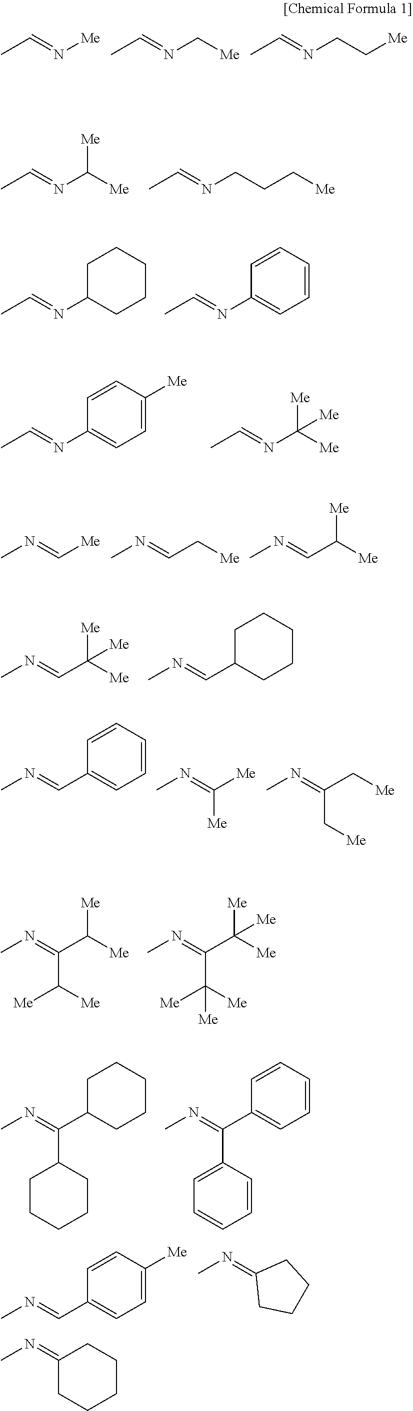

An “amide group” refers to an atomic group that remains after elimination of one hydrogen atom linked to a nitrogen atom of an amide from the amide. The amide group generally has 1 to 20 carbon atoms, and preferably 1 to 18 carbon atoms. Specific examples of the amide group include a formamide group, an acetamide group, a propionamide group, a butyramide group, a benzamide group, a trifluoroacetamide group, a pentafluorobenzamide group, a diformamide group, a diacetamide group, a dipropionamide group, a dibutyramide group, a dibenzamide group, a ditrifluoroacetamide group, and a dipentafluorobenzamide group.

An “acid imide group” refers to an atomic group that remains after elimination of one hydrogen atom linked to a nitrogen atom of an acid imide from the acid imide. The acid imide group generally has 4 to 20 carbon atoms. Specific examples of the acid imide group include groups represented by the following structural formulae.

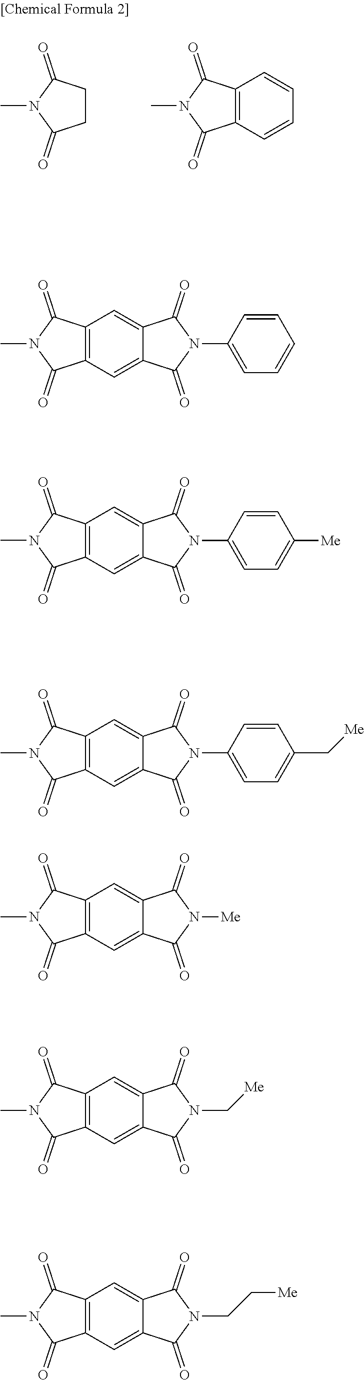

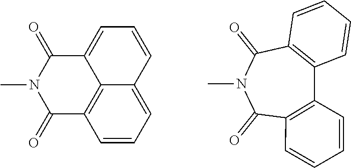 [SMILES: CN1C(=O)c2cccc3cccc(c23)C1=O ; Cn1c(=O)c2ccccc2c2ccccc2c1=O]

A “substituted oxycarbonyl group” refers to a group represented by R′—O—(C═O)—. In the formula, R′ represents an alkyl group, an aryl group, an aryl alkyl group, or a monovalent heterocyclic group.

The substituted oxycarbonyl group generally has 2 to 60 carbon atoms, and preferably 2 to 48 carbon atoms.

Specific examples of the substituted oxycarbonyl group include a methoxycarbonyl group, an ethoxycarbonyl group, a propoxycarbonyl group, an isopropoxycarbonyl group, a butoxycarbonyl group, an isobutoxycarbonyl group, a tert-butoxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenoxycarbonyl group, a naphthoxycarbonyl group, and a pyridyloxycarbonyl group.

An “alkenyl group” may be any of linear, branched, and cyclic. The linear alkenyl group generally has, excluding carbon atoms of its substituents, 2 to 30 carbon atoms, and preferably 3 to 20 carbon atoms. The branched or cyclic alkenyl group generally has, excluding carbon atoms of its substituents, 3 to 30 carbon atoms, and preferably 4 to 20 carbon atoms.

The alkenyl group may have a substituent. Specific examples of the alkenyl group include a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, and a 7-octenyl group; and substituted forms of the foregoing groups each having a substituent such as an alkyl group or an alkoxy group.

An “alkynyl group” may be any of linear, branched, and cyclic. The linear alkenyl group generally has, excluding carbon atoms of its substituents, 2 to 20 carbon atoms, and preferably 3 to 20 carbon atoms. The branched or cyclic alkenyl group generally has, excluding carbon atoms of its substituents, 4 to 30 carbon atoms, and preferably 4 to 20 carbon atoms.

The alkynyl group may have a substituent. Specific examples of the alkynyl group include an ethynyl group, a 1-propynyl group, a 2-propynyl group, a 2-butynyl group, a 3-butynyl group, a 3-pentynyl group, a 4-pentynyl group, a 1-hexynyl group, and a 5-hexynyl group; and substituted forms of the foregoing groups each having a substituent such as an alkyl group or an alkoxy group.

Examples of the π-conjugated polymer 60 according to the present embodiment include polyvinylcarbazole and derivatives thereof, polysilane and derivatives thereof, polysiloxane derivatives having an aromatic amine structure in a side chain or a main chain, polyaniline and derivatives thereof, polythiophene and derivatives thereof, polypyrrole and derivatives thereof, polyphenylenevinylene and derivatives thereof, polythienylenevinylene and derivatives thereof, and polyfluorene and derivatives thereof.

More specifically, examples of the π-conjugated polymer 60 according to the present embodiment include polymer compounds containing a constitutional unit represented by the following Formula (I) and/or a constitutional unit represented by the following Formula (II).

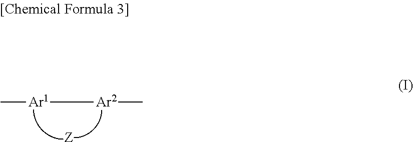

In Formula (I), Ar¹ and Ar² represent a trivalent aromatic heterocyclic group, and Z represents a group represented by the following Formula (Z-1) to Formula (Z-7).

[Chemical Formula 4]

-Ar³- (II)

In Formula (II), Ar³ represents a divalent aromatic heterocyclic group.

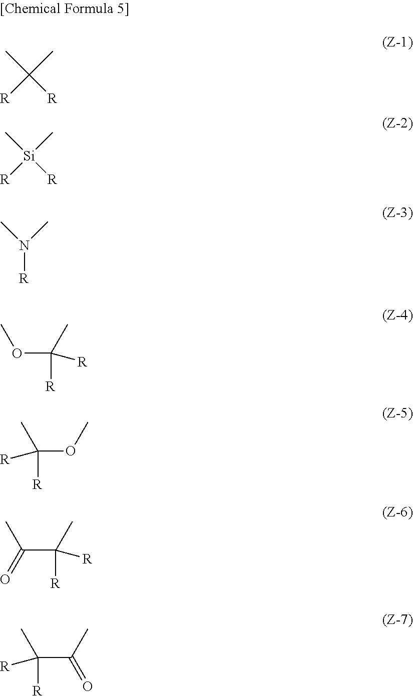

In Formula (Z-1) to (Z-7), R represents a hydrogen atom, a halogen atom, an alkyl group, an aryl group, an alkoxy group, an aryloxy group, an alkylthio group, an arylthio group, a monovalent heterocyclic group, a substituted amino group, an acyl group, an imine residue, an amide group, an acid imide group, a substituted oxycarbonyl group, an alkenyl group, an alkynyl group, a cyano group, or a nitro group. In each of Formula (Z-1) to Formula (Z-7), when two Rs are present, the two Rs may be the same as or different from each other.

Examples of the constitutional unit represented by Formula (I) include constitutional units represented by the following Formula (I-1).

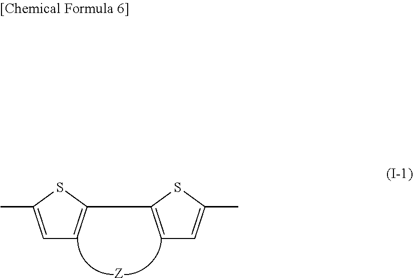

In Formula (I-1), Z has the same meaning as defined above.

Examples of the constitutional unit represented by Formula (I-1) include constitutional units represented by the following Formula (501) to Formula (505).

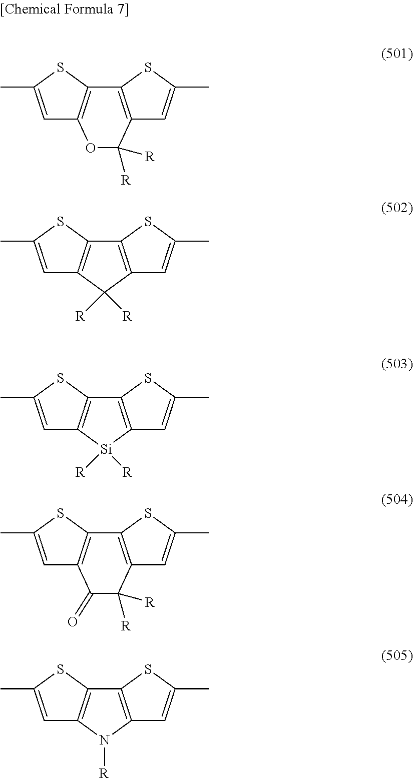

In Formula (501) to Formula (505), R has the same meaning as defined above. When two Rs are present, the two Rs may be the same as or different from each other.

The divalent aromatic heterocyclic group represented by Ar³ generally has 2 to 60 carbon atoms, preferably 4 to 60 carbon atoms, and more preferably 4 to 20 carbon atoms. The divalent aromatic heterocyclic group represented by Ar³ may have a substituent. Examples of the substituent that the divalent aromatic heterocyclic group represented by Ar³ may have include a halogen atom, an alkyl group, an aryl group, an alkoxy group, an aryloxy group, an alkylthio group, an arylthio group, a monovalent heterocyclic group, a substituted amino group, an acyl group, an imine residue, an amide group, an acid imide group, a substituted oxycarbonyl group, an alkenyl group, an alkynyl group, a cyano group, and a nitro group.

Examples of the divalent aromatic heterocyclic group represented by Ara include groups represented by the following Formula (101) to Formula (185).

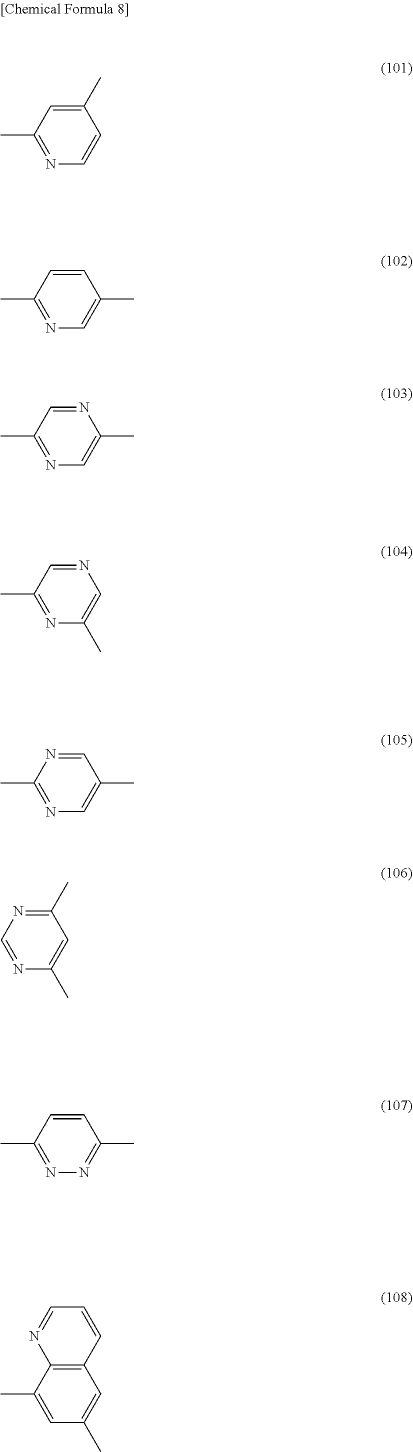

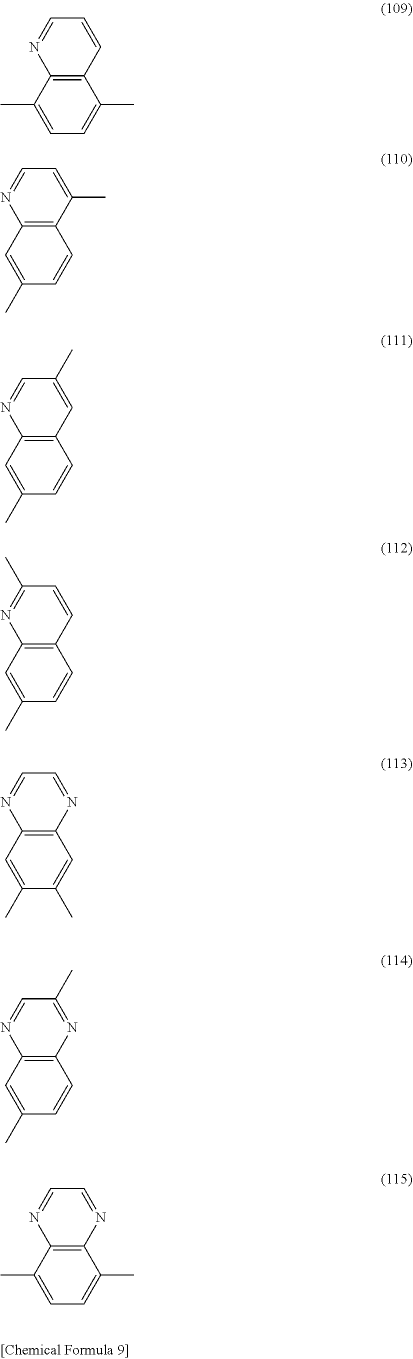

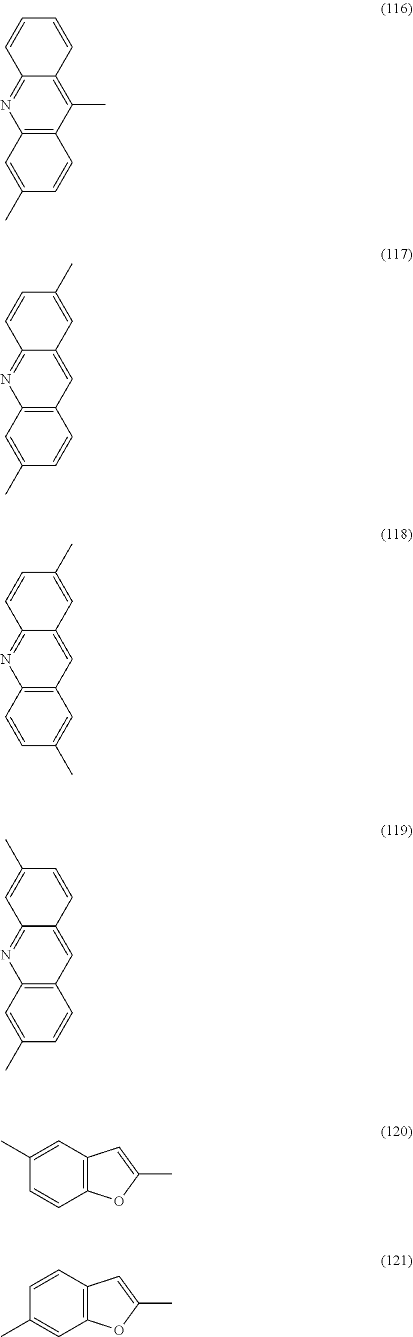

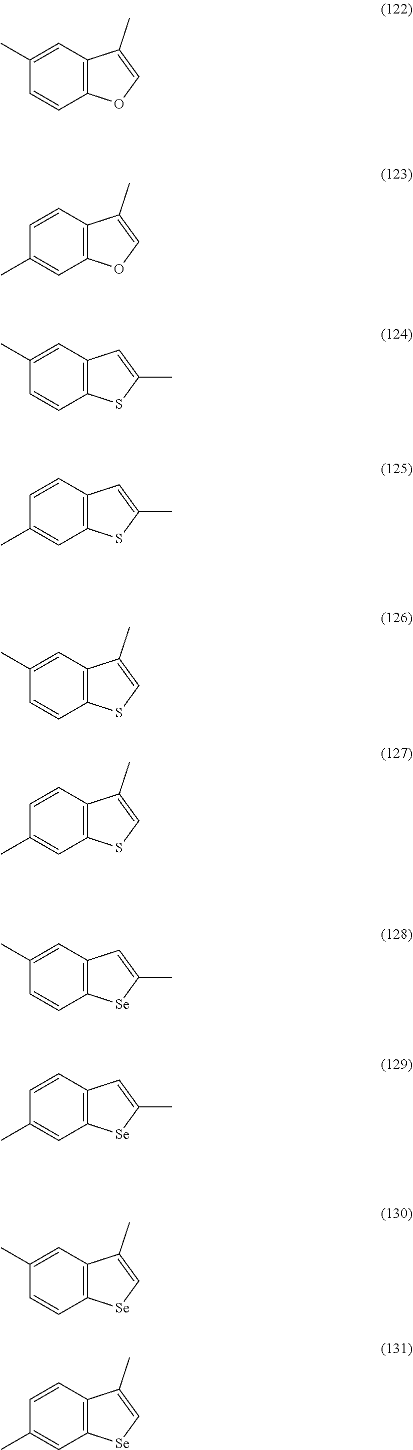

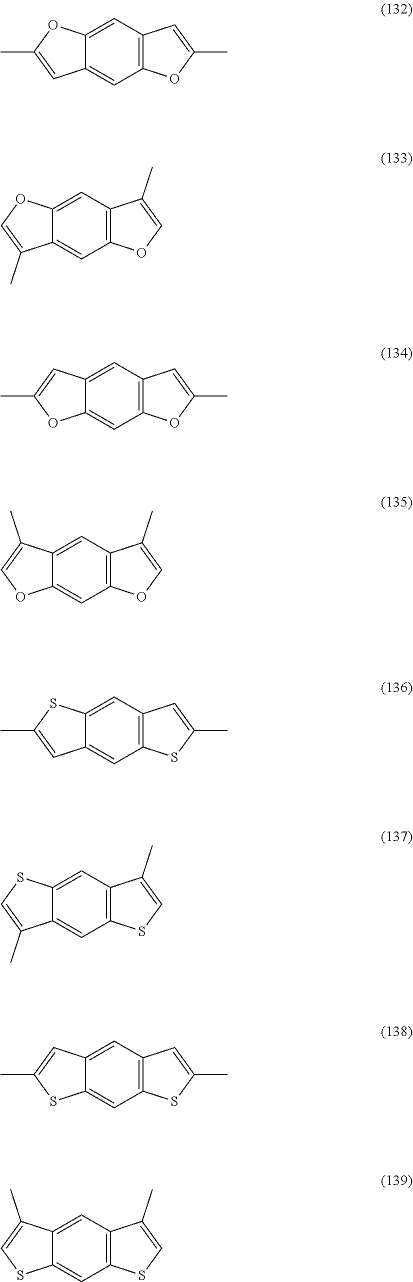

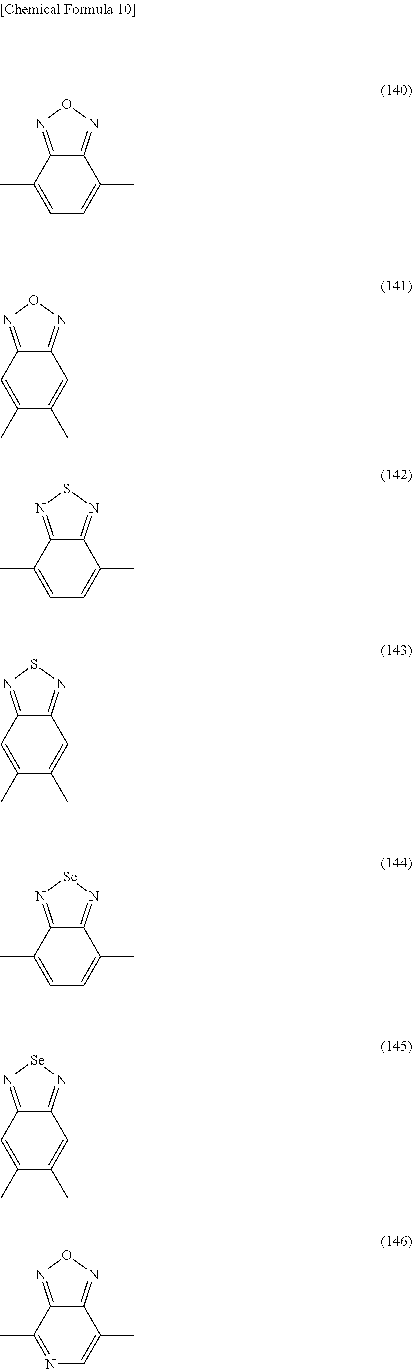

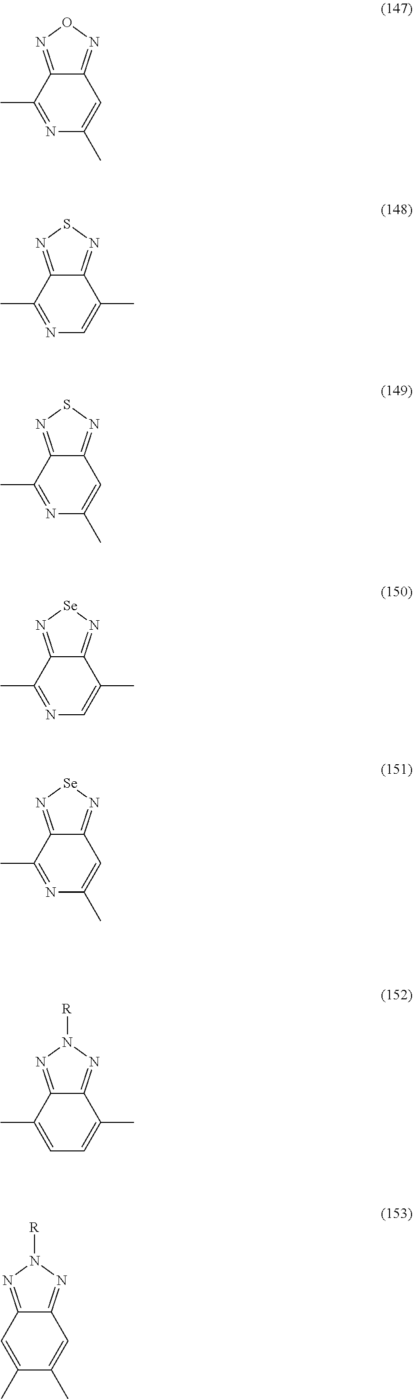

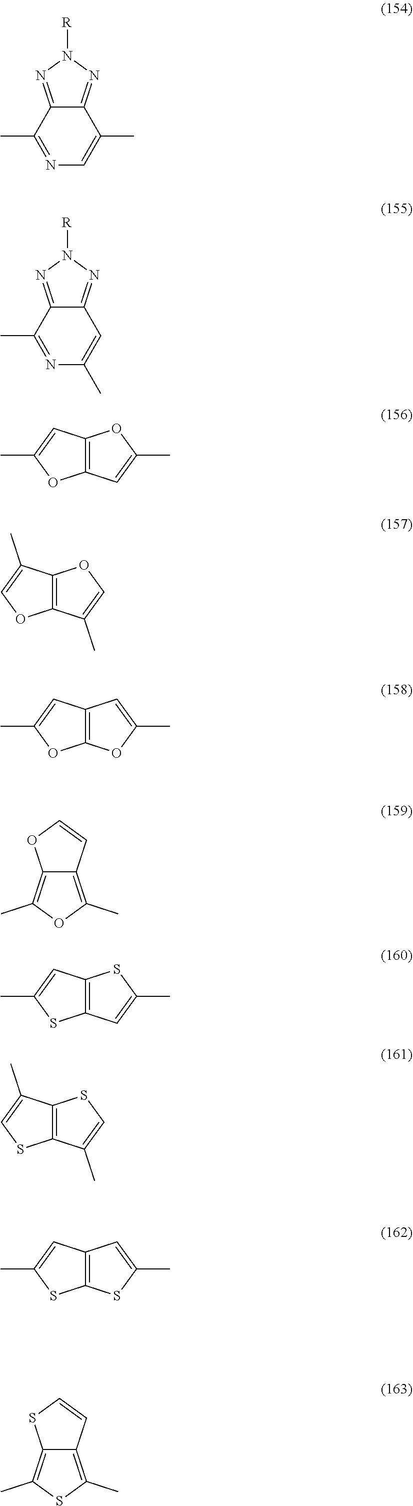

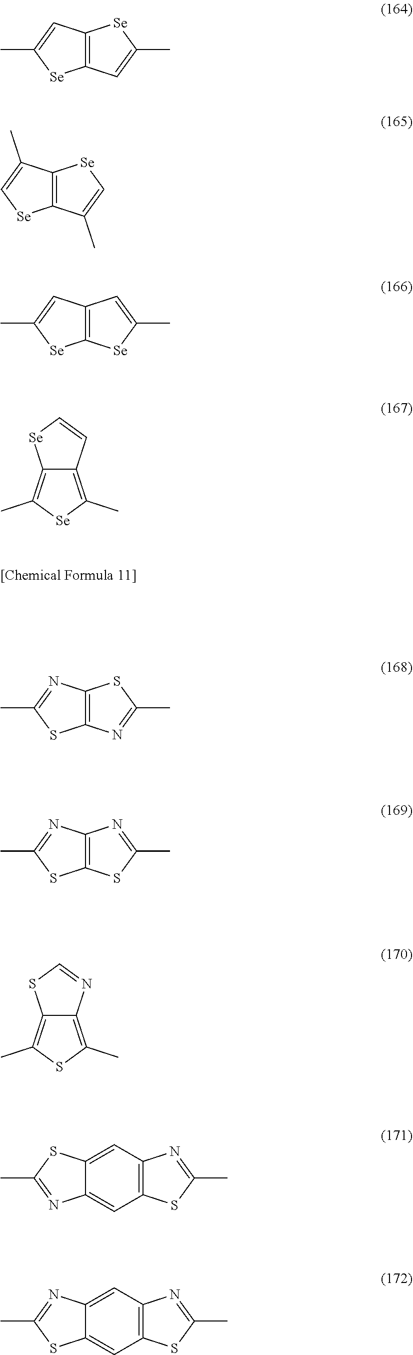

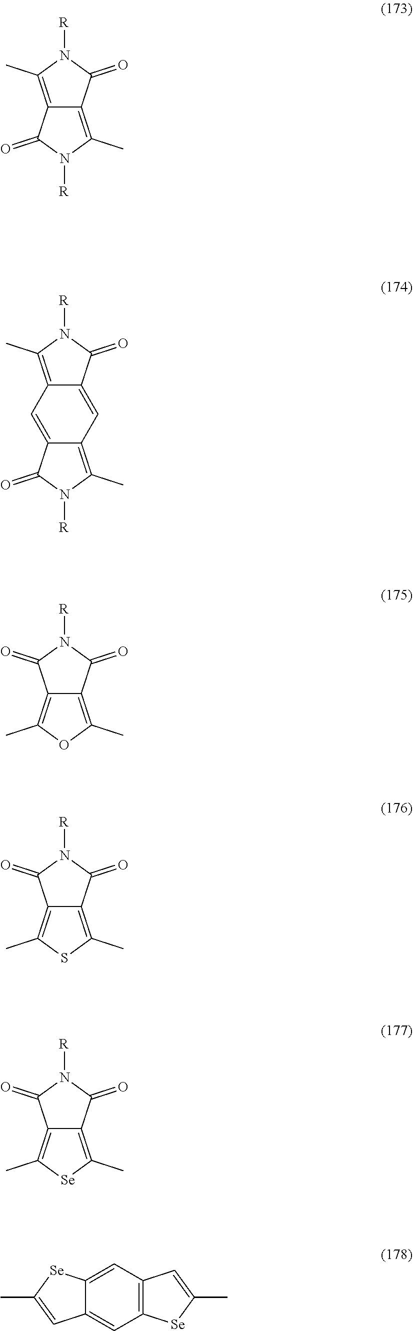

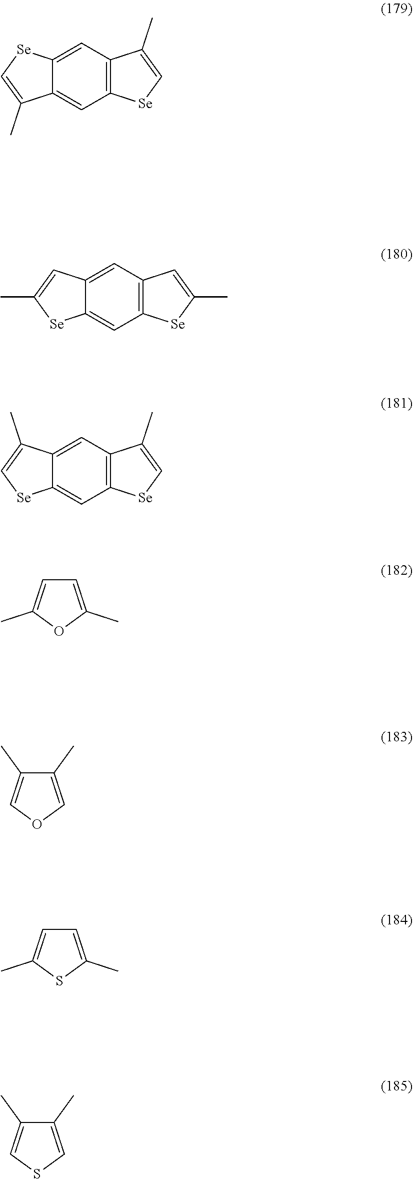

In Formula (101) to Formula (185), R has the same meaning as defined above. When a plurality of Rs are present, the plurality of Rs may be the same as or different from each other.

Examples of the constitutional unit represented by the above-described Formula (II) include constitutional units represented by the following Formula (II-1) to Formula (II-6).

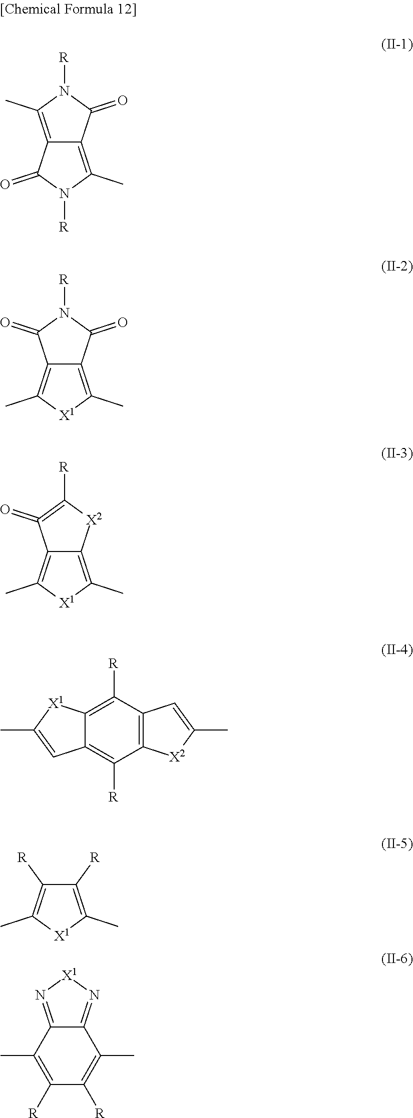

In Formula (II-1) to Formula (II-6), X¹ and X² each independently represent an oxygen atom or a sulfur atom, and R has the same meaning as defined above. When a plurality of Rs are present, the plurality of Rs may be the same as or different from each other.

From the viewpoint of availability of compounds used as raw materials, both X¹ and X² in Formula (II-1) to Formula (II-6) are preferably sulfur atoms.

The π-conjugated polymer 60 according to the present embodiment may be a polymer compound containing a constitutional unit including the thiophene skeleton.

The π-conjugated polymer 60 according to the present embodiment may contain two or more types of constitutional units represented by Formula (I), and may contain two or more types of constitutional units represented by Formula (II).

The π-conjugated polymer 60 according to the present embodiment may contain a constitutional unit represented by the following Formula (III).

[Chemical Formula 13]

-Ar⁴- (III)

In Formula (III), Ar⁴ represents an arylene group.

The arylene group represented by Ar⁴ refers to an atomic group that remains after elimination of two hydrogen atoms from an optionally substituted aromatic hydrocarbon. The aromatic hydrocarbon includes a compound having a fused ring, and a compound in which two or more rings selected from the group consisting of an independent benzene ring and fused rings are bonded directly or via a divalent group such as a vinylene group to each other.

Examples of the substituent that the aromatic hydrocarbon may have include substituents that are the same as those exemplified as substituents that the heterocyclic compound may have.

The arylene group, excluding its substituents, generally has 6 to 60 carbon atoms, and preferably 6 to 20 carbon atoms. The upper limit of the number of carbon atoms in the arylene group including substituents is 100.

Examples of the arylene group include a phenylene group (e.g., the following Formula 1 to Formula 3), a naphthalene-diyl group (e.g., the following Formula 4 to Formula 13), an anthracene-diyl group (e.g., the following Formula 14 to Formula 19), a biphenyl-diyl group (e.g., the following Formula 20 to Formula 25), a terphenyl-diyl group (e.g., the following Formula 26 to Formula 28), a fused-ring compound group (e.g., the following Formula 29 to Formula 35), a fluorene-diyl group (e.g., the following Formula 36 to Formula 38), and a benzofluorene-diyl group (e.g., the following Formula 39 to Formula 46).

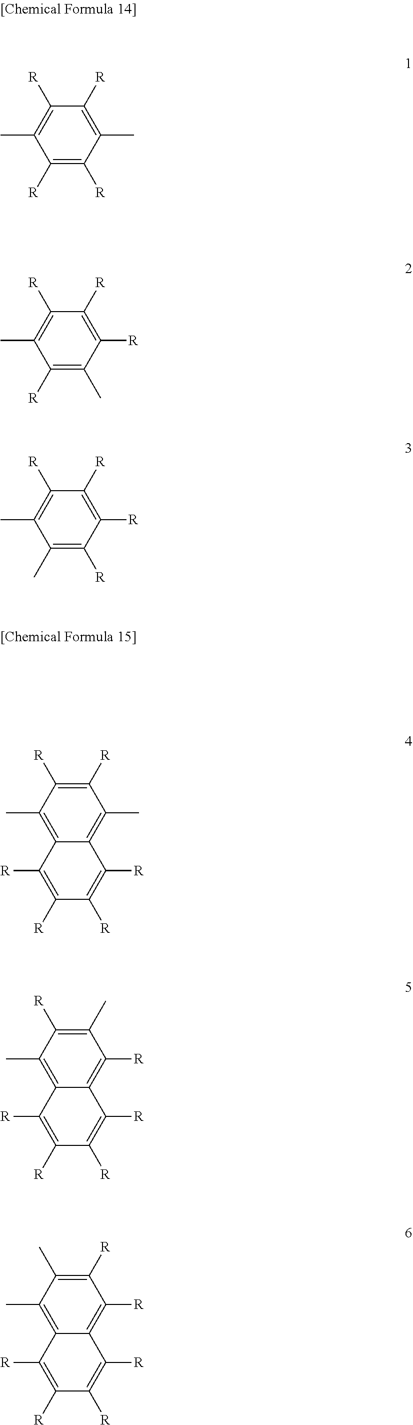

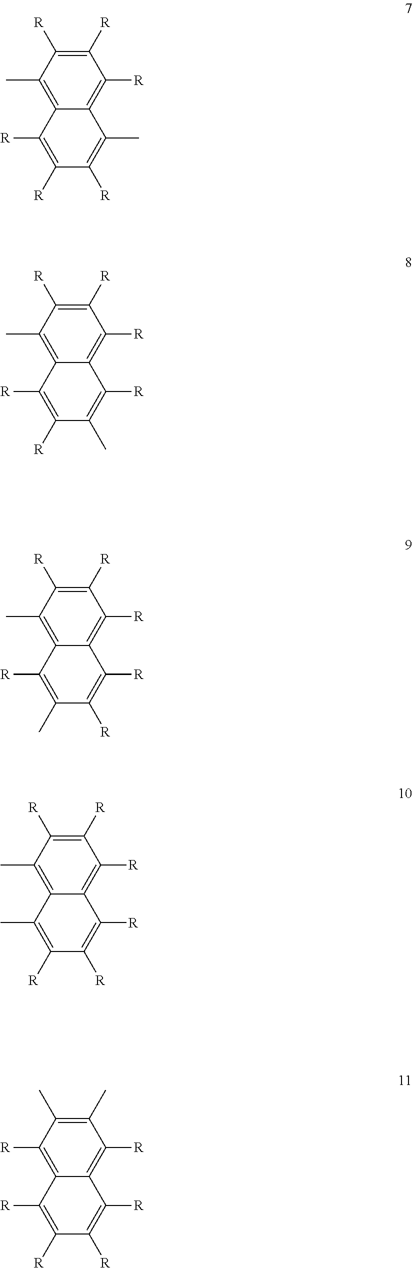

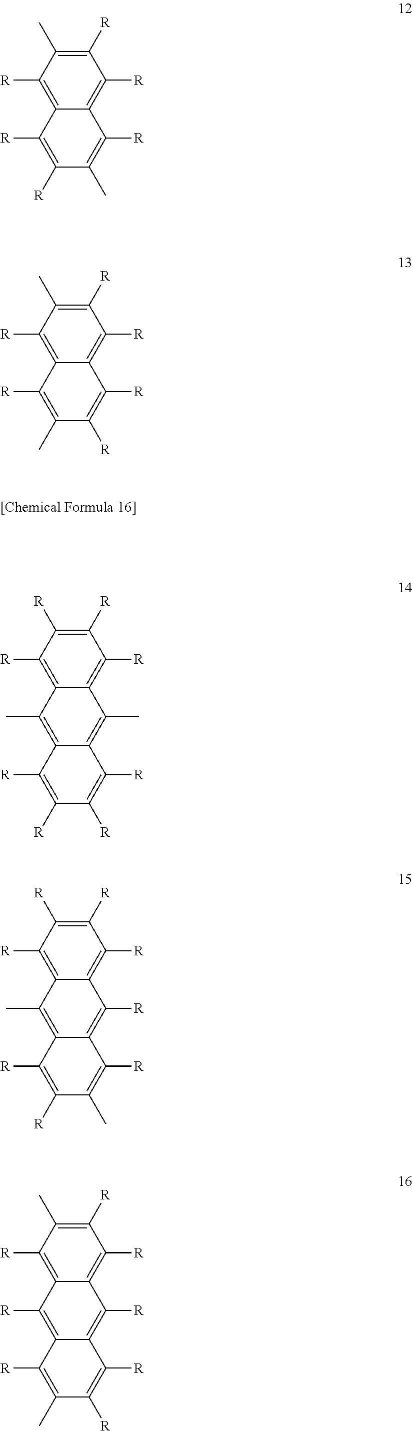

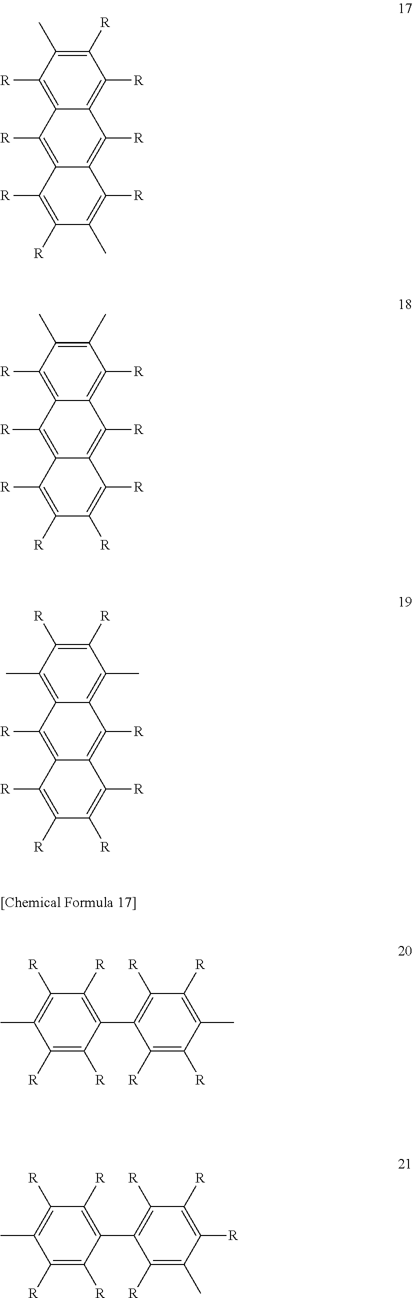

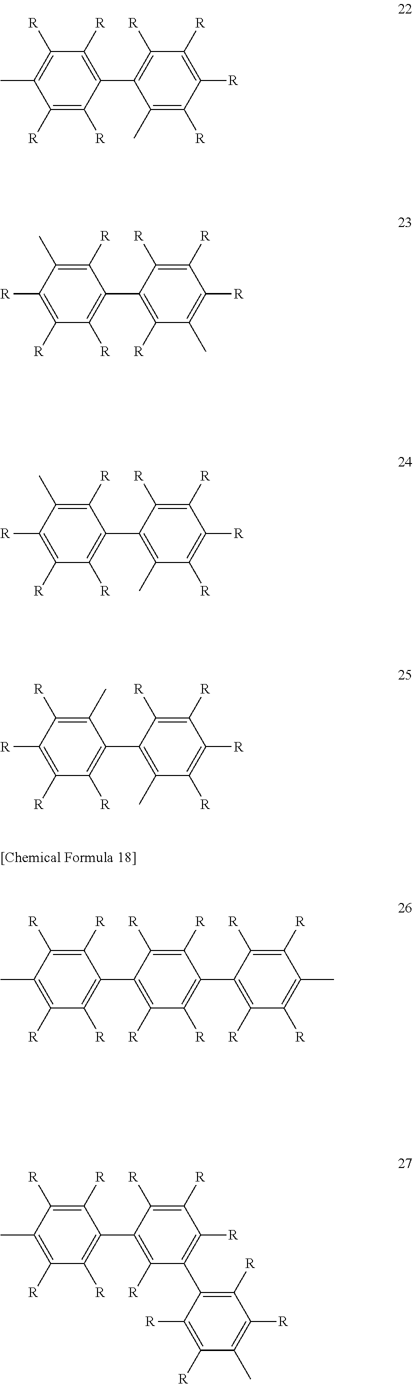

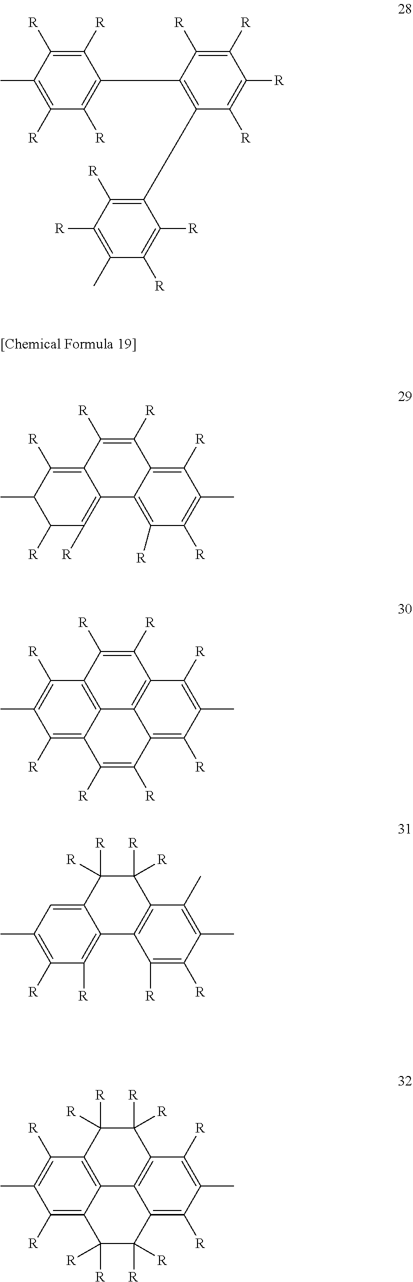

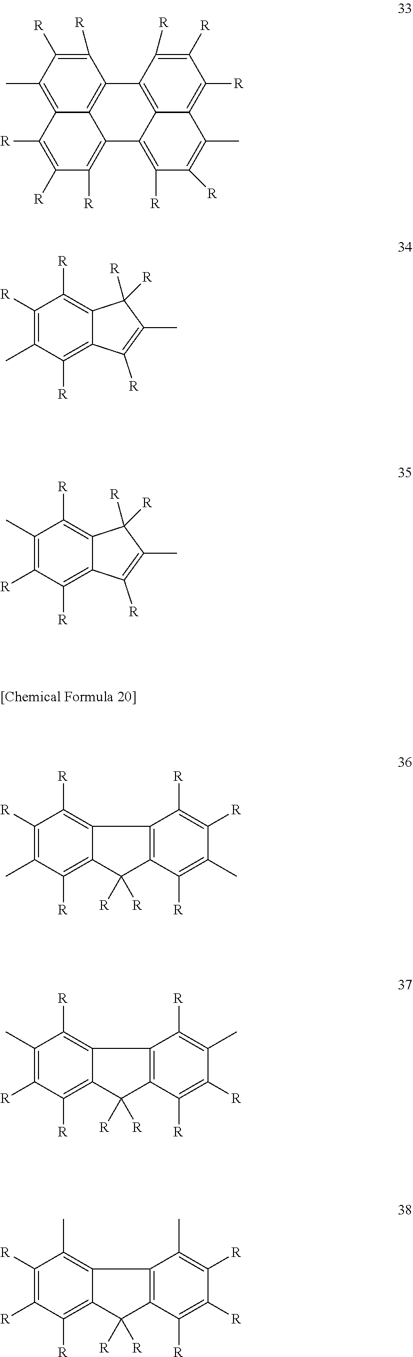

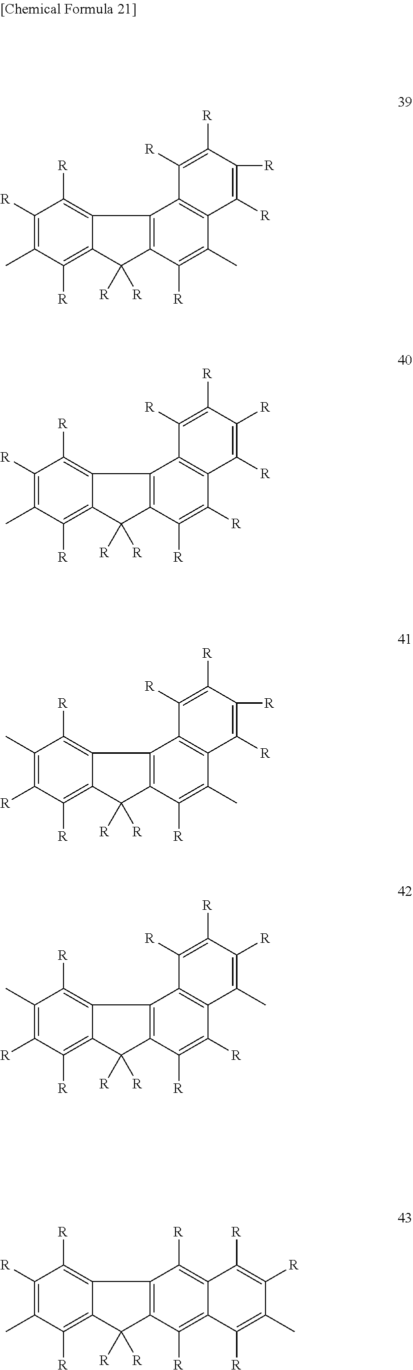

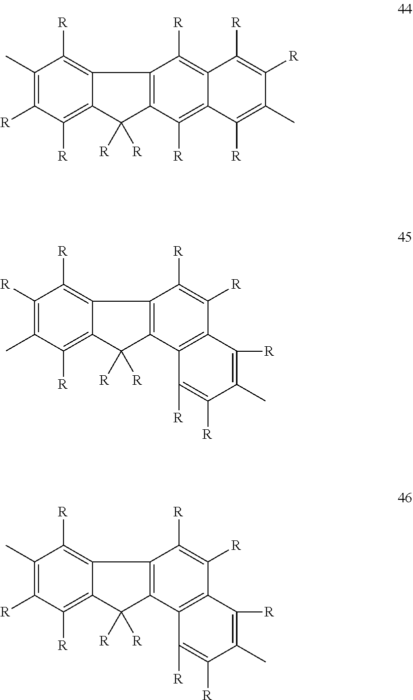

In Formula 1 to 46, R as a substituent has the same meaning as defined above. The plurality of Rs present in each formula may be the same as or different from each other.

The constitutional unit that constitutes the π-conjugated polymer 60 according to the present embodiment may be a constitutional unit in which two or more constitutional units of two or more types of constitutional units selected from the group consisting of a constitutional unit represented by Formula (I), a constitutional unit represented by Formula (II), and a constitutional unit represented by Formula (III) are combined and linked to each other.

When the π-conjugated polymer 60 according to the present embodiment contains a constitutional unit represented by Formula (I) and/or a constitutional unit represented by Formula (II), the total amount of the constitutional unit represented by Formula (I) and the constitutional unit represented by Formula (II) generally may be, relative to the total amount of all constitutional units contained in the polymer compound as 100 mol %, 20 to 100 mol %, and, from the viewpoint of improving the electric charge transportability, may be 40 to 100 mol % or 50 to 100 mol %.

Specific examples of the π-conjugated polymer 60 according to the present embodiment include polymer compounds represented by the following Formulae P-1 to P-4.

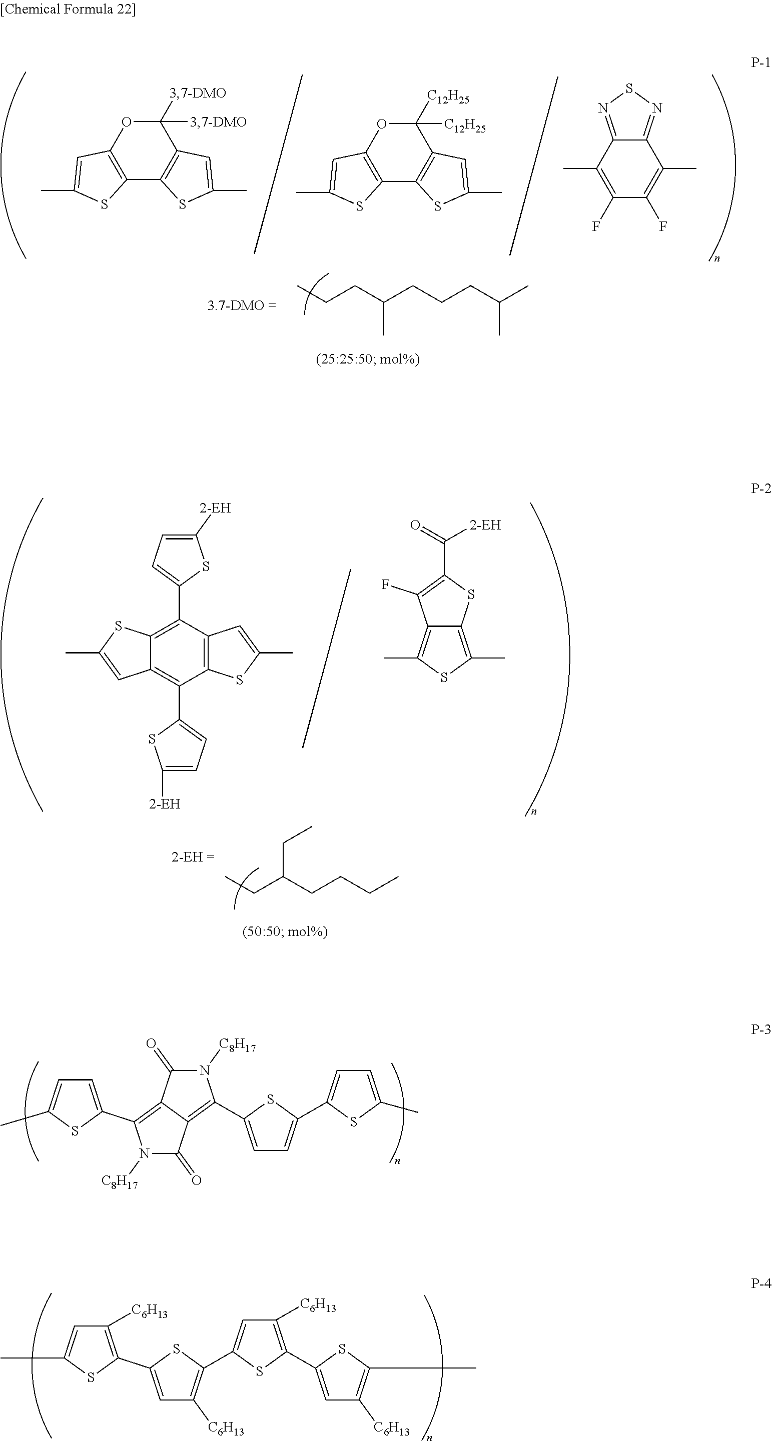

In the above-described enclosure container 20 in the step (1), a predetermined amount of the π-conjugated polymer 60 is accommodated and an oxygen absorber 50 containing active ingredients in amounts effective for the predetermined amount of the π-conjugated polymer 60 is disposed. Then, using a means and a technique suitable for the selected enclosure container 20, the space in the enclosure container 20 is made into an airtight state, so that the π-conjugated polymer 60 and the oxygen absorber 50 are enclosed in the enclosure container 20.

According to this step, the atmosphere in the enclosure container 20 becomes an atmosphere having an oxygen concentration of 1% or less. The oxygen concentration is more preferably, from the viewpoint of further efficiently suppressing the increase in the electron spin concentration, 1% or less, and still more preferably 0.5% or less.

### <Step (2)>

An active layer of the organic photoelectric conversion element according to the present embodiment contains a p-type semiconductor material (electron donating compound) and an n-type semiconductor material (electron accepting compound). The choice of the p-type semiconductor material or the n-type semiconductor material to use can be relatively made depending on the energy level of HOMO or LUMO of the selected organic semiconductor material.

The active layer, in general, has a thickness of preferably 1 nm to 100 μm, more preferably 2 nm to 1000 nm, still more preferably 5 nm to 500 nm, and particularly preferably 20 nm to 200 nm. When the organic photoelectric conversion element is applied to, for example, a solar cell, the active layer preferably has a thickness of 500 nm to 1000 nm. When the organic photoelectric conversion element is applied to, for example, a photodetector element, the active layer preferably has a thickness of 500 nm to 1000 nm.

The active layer can be produced by, for example, an application method using an ink composition (application liquid).

An example for forming the active layer, which is a main constituent of the organic photoelectric conversion element, by an application method is described below. This step of forming the active layer includes the following step (i) and step (ii).

### Step (i)

As a method for applying an ink composition to a target for application, any suitable application method can be used. As the application method, a slit coating method, a knife coating method, a spin coating method, a micro gravure coating method, a gravure coating method, a bar coating method, an inkjet printing method, a nozzle coating method, or a capillary coating method is preferred, a slit coating method, a spin coating method, a capillary coating method, or a bar coating method is more preferred, and a slit coating method or a spin coating method is still more preferred.

The ink composition for forming an active layer is applied to a target for application that is selected depending on an organic photoelectric conversion element and its production method. The ink composition for forming an active layer is applied, in a method for producing an organic photoelectric conversion element, to a functional layer that is included in an organic photoelectric conversion element and can be adjacent to the active layer. Thus, the target for application of the ink composition for forming an active layer varies depending on the layer constitution or the order of layer formation of the organic photoelectric conversion element to be manufactured. For example, when the organic photoelectric conversion element has a layer constitution of substrate/anode/hole transport layer/active layer/electron transport layer/cathode and the layers are formed starting from the left, the target for application of the ink composition is the hole transport layer. Alternatively, for example, when the organic photoelectric conversion element has a layer constitution of substrate/cathode/electron transport layer/active layer/hole transport layer/anode and the layers are formed starting from the left, the target for application of the ink composition is the electron transport layer.

### Step (ii)

As a method for removing a solvent from an applied film of the ink composition, that is, a method for drying the applied film to remove a solvent and curing the applied film, any suitable method can be used. Examples of the method for removing a solvent include drying processes using a direct heating method using a hot plate, a hot air drying method, an infrared heating drying method, a flash lamp anneal drying method, a vacuum drying method, and the like.

The step of forming an active layer may include other steps except for the step (i) and the step (ii) as long as the objects and effects of the present invention are not compromised.

The method for producing an organic photoelectric conversion element according to the present embodiment may be a method for producing an organic photoelectric conversion element including a plurality of active layers, and a production method in which the step (i) and step (ii) are repeated twice or more.

### (Ink Composition)

The ink composition that can be used in the above-described step (i) may be a solution, and may be a dispersion such as a dispersion, an emulsion, or a suspension. The ink composition according to the present embodiment is an ink composition for forming an active layer, and contains a π-conjugated polymer, which is a p-type semiconductor material, an n-type semiconductor material, and a first solvent, and in addition, if necessary, may contain a second solvent.

The ink composition may contain one type of a p-type semiconductor material (π-conjugated polymer 60) alone, or may contain two or more types of p-type semiconductor materials in combination in any ratio.

(n-Type Semiconductor Material)

The n-type semiconductor material (electron accepting compound) may be a low molecular weight compound or a polymer compound.

Examples of the n-type semiconductor material as a low molecular weight compound include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, fullerenes such as C₆₀ fullerene and derivatives thereof, and phenanthrene derivatives such as bathocuproine.

Examples of the n-type semiconductor material as a polymer compound include polyvinylcarbazole and derivatives thereof, polysilane and derivatives thereof, polysiloxane derivatives having an aromatic amine structure in a side chain or a main chain, polyaniline and derivatives thereof, polythiophene and derivatives thereof, polypyrrole and derivatives thereof, polyphenylenevinylene and derivatives thereof, polythienylenevinylene and derivatives thereof, polyquinoline and derivatives thereof, polyquinoxaline and derivatives thereof, and polyfluorene and derivatives thereof.

The n-type semiconductor material is preferably at least one selected from the group consisting of fullerenes and fullerene derivatives, and more preferably fullerene derivatives.

Examples of the fullerene include C₆₀ fullerene, C₇₀ fullerene, C₇₆ fullerene, C₇₈ fullerene, and C₈₄ fullerene. Examples of the fullerene derivative include derivatives of these fullerenes. The fullerene derivative refers to a compound in which at least a part of a fullerene is modified.

Examples of the fullerene derivative include compounds represented by the following Formula (N-1) to Formula (N-4).

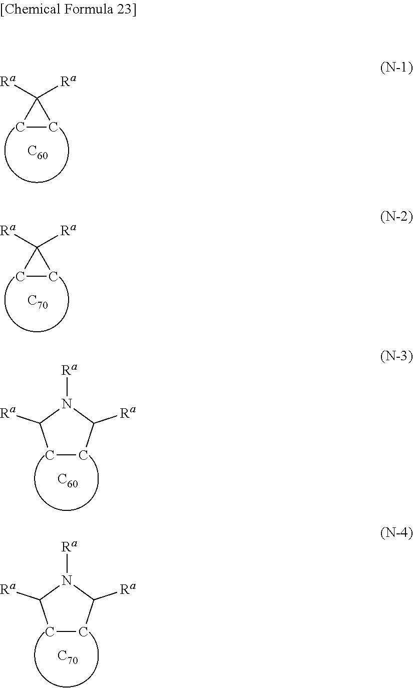

In Formula (N-1) to Formula (N-4), R^{a} represents an alkyl group, an aryl group, a monovalent heterocyclic group, or a group having an ester structure. The plurality of Ras may be the same as or different from each other.

In Formula (N-1) to Formula (N-4), R^{b} represents an alkyl group or an aryl group. The plurality of R^{b}s may be the same as or different from each other.

Examples of the group having an ester structure represented by R^{a} include groups represented by the following Formula (19).

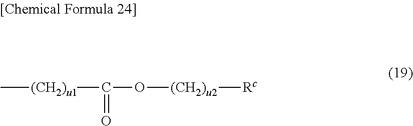

In Formula (19), u1 represents an integer of 1 to 6. The symbol u2 represents an integer of 0 to 6. R^{c} represents an alkyl group, an aryl group, or a monovalent heterocyclic group.

Examples of the C₆₀ fullerene derivative include the following compounds.

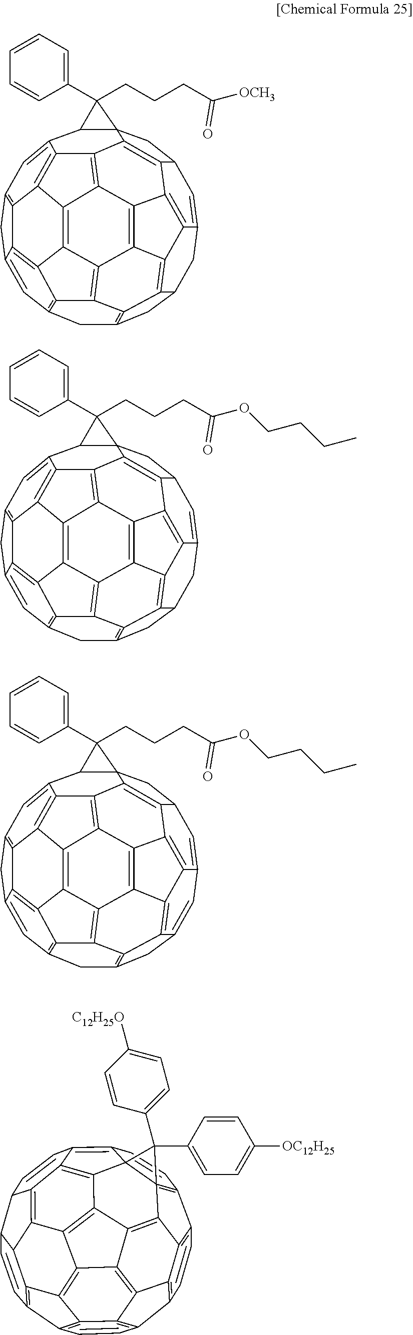

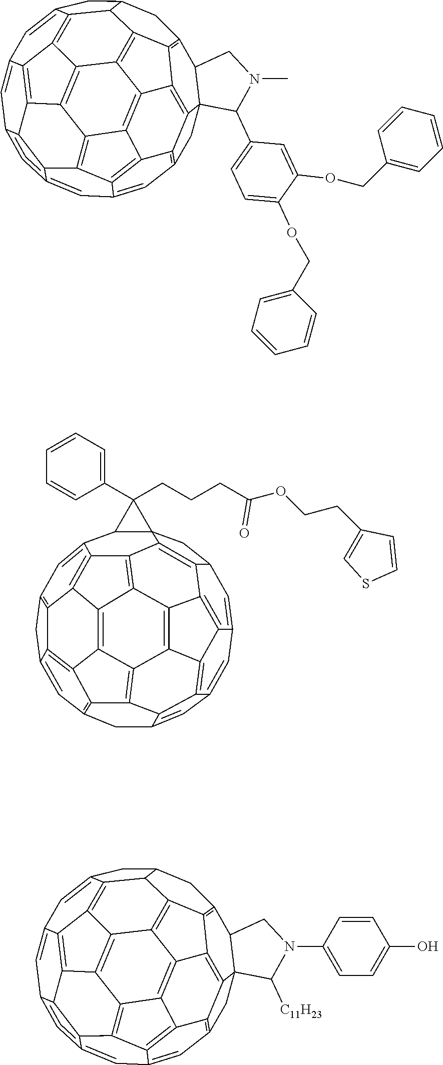

Examples of the C₇₀ fullerene derivative include the following compounds.

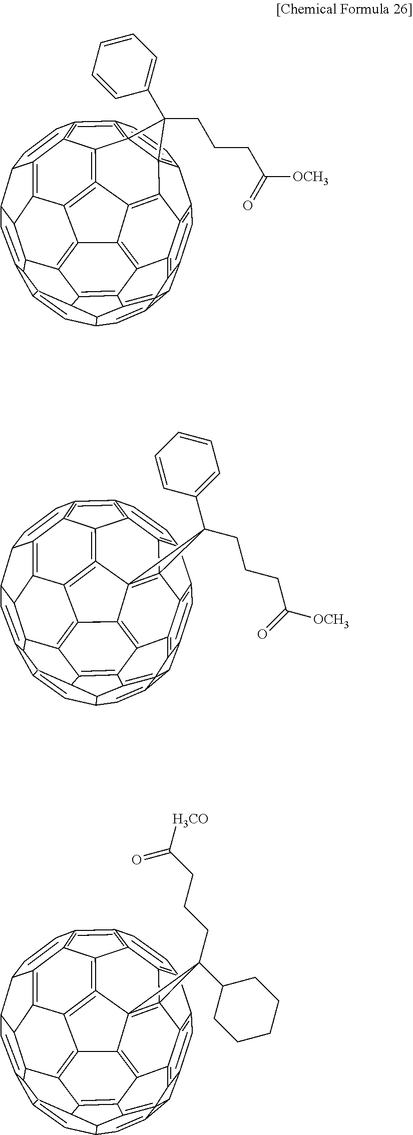

Specific examples of the fullerene derivative include [6,6]-phenyl C61 butyric acid methyl ester (C60PCBM), [6,6]-phenyl C71 butyric acid methyl ester (C70PCBM), [6,6]-phenyl C85 butyric acid methyl ester (C84PCBM), and [6,6]-thienyl C61 butyric acid methyl ester.

The ink composition may contain one type of an n-type semiconductor material alone, or may contain two or more types of n-type semiconductor materials in combination in any ratio.

### (First Solvent)

The solvent may be selected in consideration of solubility of the selected p-type semiconductor material and n-type semiconductor material, and properties required for a drying condition for forming an active layer (e.g., boiling point). The first solvent as a main solvent is an aromatic hydrocarbon optionally having a substituent (e.g., an alkyl group or a halogen atom) (hereinafter, simply referred to as an “aromatic hydrocarbon”). The first solvent is preferably selected in consideration of solubilities of the selected p-type semiconductor material and n-type semiconductor material.

Examples of the aromatic hydrocarbon include toluene, xylene (e.g., o-xylene, m-xylene, and p-xylene), trimethylbenzene (e.g., mesitylene and 1,2,4-trimethylbenzene (pseudocumene)), butylbenzene (e.g., n-butylbenzene, sec-butylbenzene, and tert-butylbenzene), methylnaphthalene (e.g., 1-methylnaphthalene), tetralin, indan, chlorobenzene, and dichlorobenzene (o-dichlorobenzene).

The first solvent may contain one type of the aromatic hydrocarbon alone, or may contain two or more types of the aromatic hydrocarbons. The first solvent preferably contains one type of the aromatic hydrocarbon alone.

The first solvent preferably contains at least one selected from the group consisting of toluene, o-xylene, m-xylene, p-xylene, mesitylene, pseudocumene, n-butylbenzene, sec-butylbenzene, tert-butylbenzene, methylnaphthalene, tetralin, indan, chlorobenzene, and o-dichlorobenzene, and more preferably is o-xylene, pseudocumene, tetralin, chlorobenzene, or o-dichlorobenzene.

### (Second Solvent)

The second solvent is preferably a solvent selected from the viewpoint of increasing solubility of, in particular, an n-type semiconductor material. Examples of the second solvent include ketone solvents such as acetone, methyl ethyl ketone, cyclohexanone, acetophenone, and propiophenone; and ester solvents such as ethyl acetate, butyl acetate, phenyl acetate, ethylcellosolve acetate, methyl benzoate, butyl benzoate, and benzyl benzoate.

The second solvent is preferably, from the viewpoint of reducing a dark current, acetophenone, propiophenone, or benzyl benzoate.

### (Combination of First Solvent and Second Solvent)

Examples of combination of the first solvent and the second solvent include combinations shown in Table 1 below.

TABLE 1

| First solvent | Second solvent |
|---|---|
| Pseudocumene | Propiophenone |
| Pseudocumene | Benzyl benzoate |
| Tetralin | Propiophenone |
| o-Xylene | Acetophenone |

### (Weight Ratio Between First Solvent and Second Solvent)

The weight ratio of the first solvent as a main solvent to the second solvent (first solvent/second solvent) is preferably, from the viewpoint of further improving the solubility of the p-type semiconductor material and the n-type semiconductor material, within a range of 85/15 to 95/5.

### (Total Weight Percent of First Solvent and Second Solvent in Ink Composition)

The total weight of the first solvent and the second solvent contained in the ink composition is, from the viewpoint of further improving the solubility of the p-type semiconductor material and the n-type semiconductor material, preferably, relative to the total weight of the ink composition as 100% by weight, 90% by weight or more, more preferably 92% by weight or more, and still more preferably 95% by weight or more. On the other hand, from the viewpoint of facilitating formation of a film at least having a certain thickness while achieving higher contents of the p-type semiconductor material and the n-type semiconductor material in the ink composition, the total weight of the first solvent and the second solvent is preferably 99% by weight or less, more preferably 98% by weight or less, and still more preferably 97.5% by weight or less.

### (Optional Solvent)

The ink composition may contain an optional solvent except for the first solvent and the second solvent. The content of the optional solvent is preferably, relative to the total weight of the solvents contained in the ink composition as 100% by weight, 5% by weight or less, more preferably 3% by weight or less, and still more preferably 1% by weight or less. The optional solvent preferably has a boiling point that is higher than that of the second solvent.

### (Optional Ingredients)

The ink composition may contain, as long as the objects and effects of the present invention are not compromised, optional ingredients such as ultraviolet absorbers, antioxidants, sensitizers for improving the effect of generating electric charges by absorbed light, and light stabilizers for improving UV-light stability in addition to the first solvent, the second solvent, the p-type semiconductor material, and the n-type semiconductor material.

(Concentration of p-Type Semiconductor Material and n-Type Semiconductor Material in Ink Composition)

The total concentration of the p-type semiconductor material and the n-type semiconductor material in the ink composition is preferably 0.01% by weight or more and 20% by weight or less, more preferably 0.01% by weight or more and 10% by weight or less, still more preferably 0.01% by weight or more and 5% by weight or less, and particularly preferably 0.1% by weight or more and 5% by weight or less. The p-type semiconductor material and the n-type semiconductor material may be dissolved or dispersed in the ink composition. Preferably at least a part of the p-type semiconductor material and the n-type semiconductor material are dissolved, and more preferably the p-type semiconductor material and the n-type semiconductor material are totally dissolved.

### (Preparation of Ink Composition)

The ink composition can be prepared by publicly known methods. For example, the ink composition can be prepared by a method in which a first solvent and a second solvent are mixed to give a mixed solvent, and a p-type semiconductor material and an n-type semiconductor material are added to the mixed solvent; and a method in which a p-type semiconductor material is added to a first solvent, an n-type semiconductor material is added to a second solvent, and the first solvent containing the p-type semiconductor material and the second solvent containing the n-type semiconductor material are mixed.

The first solvent and second solvent and the p-type semiconductor material and n-type semiconductor material may be mixed under heating at a temperature that is equal to or lower than the boiling point of the solvents.

The first solvent and second solvent and the p-type semiconductor material and n-type semiconductor material may be mixed, then the resulting mixture may be filtered through a filter, and the resulting filtrate may be used as an ink composition. As the filter, a filter formed of a fluorocarbon resin such as polytetrafluoroethylene (PTFE) can be used.

According to the method for producing an organic photoelectric conversion element, a π-conjugated polymer 60 as a raw material of an active layer can be stored while increase in the electron spin concentration of the π-conjugated polymer 60, that is, time-dependent deterioration of the π-conjugated polymer 60 is effectively prevented. Thus, an organic photoelectric conversion element can be produced independent of the timing of production of the π-conjugated polymer 60, and therefore on-demand production of the organic photoelectric conversion element using the stored π-conjugated polymer 60 becomes possible.

In addition, the storage method according to the present embodiment can be carried out by easy and convenient steps, and can realize, further long-term and further stable storage of a π-conjugated polymer 60 while increase in the electron spin concentration of a π-conjugated polymer 60, that is, time-dependent deterioration of the π-conjugated polymer 60 is effectively prevented.

### 2. Organic Photoelectric Conversion Element

An organic photoelectric conversion element according to the present embodiment comprises a pair of electrodes including an anode and a cathode, and an active layer that is disposed between the pair of electrodes and includes a π-conjugated polymer 60 as an organic semiconductor material.

Components which the organic photoelectric conversion element according to the present embodiment may comprise other than the above-described active layer, and steps of forming the components are described below.

### (Substrate)

The organic photoelectric conversion element is generally formed on a substrate. On the substrate, in general, electrodes including a cathode and an anode are formed. Materials of the substrate are not particularly limited as long as the materials do not undergo a significant chemical change during the formation of a layer containing organic compounds. Examples of the material of the substrate include glass, plastics, polymer films, and silicon. As the substrate, a substrate on which an electrode (described later) is formed, or a substrate on which a layer of an electroconductive material that can function as an electrode is formed by patterning can be prepared and used. Examples of the substrate on which a layer of an electroconductive material is formed include a glass substrate on which a layer of indium tin oxide (ITO) is formed.

### (Electrode)

Examples of materials of a transparent or semi-transparent electrode include an electroconductive metal oxide film and a semi-transparent metallic thin film. Specific examples include indium oxide, zinc oxide, tin oxide, a composite material of the foregoing as ITO, indium zinc oxide (IZO), electroconductive materials such as NESA, gold, platinum, silver, and copper. As materials of the transparent or semi-transparent electrode, ITO, IZO, and tin oxide are preferred. As the electrode, an electroconductive transparent film formed of organic compounds such as polyaniline and derivatives thereof, polythiophene and derivatives thereof, and the like as materials. The transparent or semi-transparent electrode may be an anode or a cathode. When the substrate is opaque, the opposite electrode to the electrode on the opaque substrate (i.e., an electrode farther from the substrate) is preferably a transparent or semi-transparent electrode.

When one electrode of the pair of electrodes is transparent or semi-transparent, the other electrode can be an electrode having low optical transparency. Examples of materials of the electrode having low optical transparency include metals and electroconductive polymers. Specific examples of the material of the electrode having low optical transparency include metals such as lithium, sodium, potassium, rubidium, caesium, magnesium, calcium, strontium, barium, aluminum, scandium, vanadium, zinc, yttrium, indium, cerium, samarium, europium, terbium, and ytterbium; an alloy of two or more of the foregoing metals; an alloy of one or more of the foregoing metals and one or more metals selected from the group consisting of gold, silver, platinum, copper, manganese, titanium, cobalt, nickel, tungsten, and tin; graphite; a graphite intercalation compound; polyaniline and derivatives thereof; and polythiophene and derivatives thereof. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The electrode can be formed by using any suitable hitherto known forming methods. Examples of the method for forming the electrode include a vacuum deposition method, a sputtering method, an ion plating method, and a plating method.

### (Intermediate Layer)

The organic photoelectric conversion element according to the present embodiment may comprise an additional intermediate layer such as a charge transport layer (an electron transport layer, a hole transport layer, an electron injection layer, or a hole injection layer) as an optional constituent for improving its properties such as photoelectric conversion efficiency.

As materials used in the intermediate layer, suitable hitherto known materials can be used. Examples of the material of the intermediate layer include halides and oxides of alkali metals or alkaline-earth metals, such as lithium fluoride.

Examples of the material used in the intermediate layer include fine particles of an inorganic semiconductive material such as titanium oxide, and a mixture of poly(3,4-ethylenedioxythiophene) (PEDOT) and poly(4-styrene sulfonate) (PSS) (PEDOT:PSS).

The organic photoelectric conversion element may comprise a hole transport layer between the anode and the active layer. The hole transport layer has a function of transporting a hole from the active layer to the electrode.

A hole transport layer that is disposed in contact with the anode is sometimes referred to as a hole injection layer. The hole transport layer (hole injection layer) that is disposed in contact with the anode has a function of promoting injection of a hole into the anode. The hole transport layer (hole injection layer) may be in contact with the active layer.

The hole transport layer contains a hole transport material. Examples of the hole transport material include polythiophene and derivatives thereof, aromatic amine compounds, a polymer compound containing a constitutional unit having an aromatic amine residue, CuSCN, CuI, NiO, and molybdenum oxide (MoO₃).

The organic photoelectric conversion element may comprise an electron transport layer between the cathode and the active layer. The electron transport layer has a function of transporting an electron from the active layer to the cathode. The electron transport layer may be in contact with the cathode. The electron transport layer may be in contact with the active layer.

The electron transport layer contains an electron transport material. Examples of the electron transport material include nanoparticles of zinc oxide, nanoparticles of gallium-doped zinc oxide, nanoparticles of aluminum-doped zinc oxide, polyethylenimine, ethoxylated polyethylenimine, and PFN-P2.

The intermediate layer can be formed by an application method that is the same as that previously described in the method for producing the active layer.

### (Sealing Layer)

The organic photoelectric conversion element according to the present embodiment may further have a sealing layer. The sealing layer can be disposed on a side of an electrode that is farther from the substrate. The sealing layer can be formed by using a material having water-blocking properties (water vapor barrier properties) or oxygen-blocking properties (oxygen barrier properties), and using a method suitable for the selected material.

### (Application of Organic Photoelectric Conversion Element)

The organic photoelectric conversion element according to the present embodiment can generate photoelectromotive force between the electrodes by irradiation with light, and can be operated as a solar cell. A plurality of the solar cells can be integrated to form a film solar battery module.

The organic photoelectric conversion element according to the present embodiment can generate a photoelectric current by irradiating with light from the transparent or semi-transparent electrode side while a voltage is applied between electrodes, and can be operated as a photodetector element (photosensor). A plurality of the photosensors can be integrated and used as an image sensor.

### 3. Reagent Package

A reagent package 10 according to the present embodiment can be suitably applied to the above-described method for producing an organic photoelectric conversion element and the above-described method for storing a π-conjugated polymer 60.

As shown in FIG. 1, the reagent package 10 according to the present embodiment contains a π-conjugated polymer 60 for forming an active layer of an organic photoelectric conversion element; an enclosure container 20 enclosing the π-conjugated polymer 60 in an airtight state, in which the enclosure container 20 has gas barrier properties and the π-conjugated polymer 60 can be enclosed in and taken out of the enclosure container 20 as desired; and an oxygen absorber 50 that is provided so as to come into contact with the atmosphere in the enclosure container 20 in an airtight state, in which the atmosphere has an oxygen concentration of 1% or less.

In the exemplary constitution shown in FIG. 1, the oxygen absorbers 50 are provided both in the bottle-shaped container as an enclosure container 20 and in the bag-shaped container 40. Specifically, one oxygen absorber 50 is mounted on the recessed portion 36a of the inner lid 36 of the bottle-shaped container 30, and three oxygen absorbers 50 are further enclosed in the bag-shaped container 40 but outside the bottle-shaped container 30.

The constitutions, materials, production methods, and the like of the organic photoelectric conversion element, the π-conjugated polymer 60, the enclosure container 20, and the oxygen absorber 50 involved in the reagent package 10 according to the present embodiment are as described above.

The reagent package 10 according to the present embodiment has a simple constitution and can realize further long-term and further stable storage of the π-conjugated polymer 60 while increase in the electron spin concentration of the π-conjugated polymer 60, that is, time-dependent deterioration of the π-conjugated polymer 60 is effectively prevented.

### EXAMPLES

The following examples are provided for the purpose of further detailed description of the present invention. The present invention is not limited to the examples.

In the present examples, as p-type semiconductor materials and n-type semiconductor materials, polymer compounds and compounds having constitutional units and compositions as shown in the following Table 2 were used.

TABLE 2

| | Com- | |
|---|---|---|
| | pound | Constitutional unit and composition |
| p-Type semi- con- ductor material | P-1 | 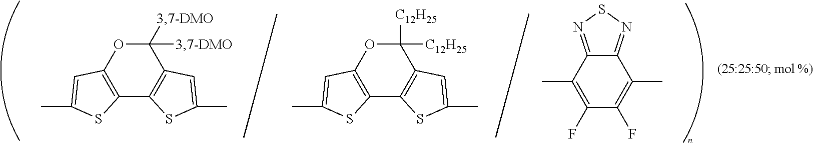 |
| | | 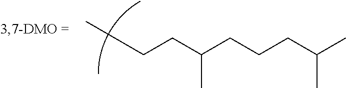 |
| | P-2 | 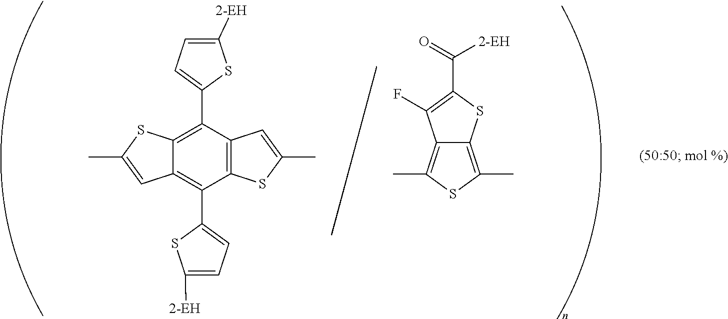 |
| | | 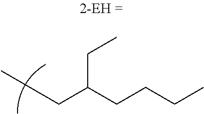 |
| | P-3 | 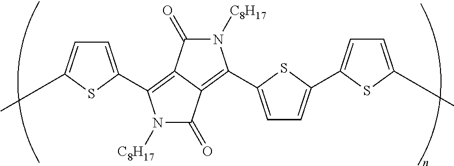 |
| | P-4 | 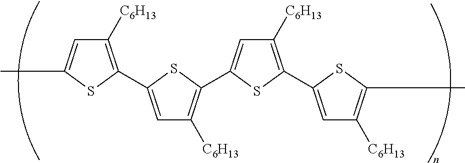 |
| | C-1 | 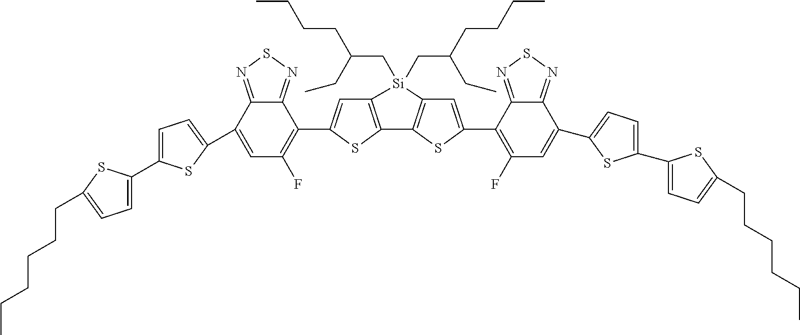 [SMILES: CCCCCCc1ccc(-c2ccc(-c3cc(F)c(-c4cc5c(s4)-c4sc(-c6c(F)cc(-c7ccc(-c8ccc(CCCCCC)s8)s7)c7nsnc67)cc4[Si]5(CC(CC)CCCC)CC(CC)CCCC)c4nsnc34)s2)s1] |
| n-Type semi- con- ductor material | N-1 | 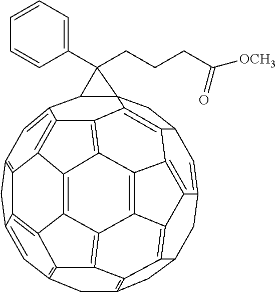 [SMILES: COC(=O)CCCC1(c2ccccc2)C2c3cc4c5c6c(cc7c8c9c%10c%11c%12c%13c%14c%15c(c%16c3c5c3c%16c%14c%12c9c3c68)C21CC%15C=C%13CC%11CC=%10C7)C4] |

The polymer compound P-1 was synthesized with reference to a method described in WO 2013/051676 (band gap: 1.38 eV, maximum absorption wavelength: 780 nm).

As the polymer compound P-2, PCE10 (trade name, manufactured by 1-Material) was obtained and used (band gap: 1.59 eV, maximum absorption wavelength: 680 nm).

As the polymer compound P-3, PDPP3T (trade name, manufactured by Lumtec) was obtained and used (band gap: 1.24 eV, maximum absorption wavelength: 850 nm).

As the polymer compound P-4, Poly(3-hexylthiophene-2,5-diyl) (trade name, manufactured by Sigma-Aldrich) was obtained and used (band gap: 2.00 eV, maximum absorption wavelength: 500 nm).

As the compound C-1, DTS(FBTTh2)2 (trade name, manufactured by 1-Material) was obtained and used.

As the compound N-1 (C60PCBM), E100 (trade name, manufactured by Frontier Carbon Corporation) was obtained and used.

### (Preparation of Ink Composition)

Using the above-described polymer compounds or compounds and solvents, ink compositions for forming active layers were prepared. Solvents used and boiling points (bp) of the solvents are shown in the following Table 3.

TABLE 3

| Solvent | bp (° C.) |
|---|---|
| Pseudocumene | 169 |
| Benzyl benzoate | 323 |

### Preparation Example 1

Pseudocumene was used as a first solvent, and benzyl benzoate was used as a second solvent. The first solvent and the second solvent were mixed in a weight ratio of 90:10 to prepare a mixed solvent. With the prepared mixed solvent, 1.44% by weight (relative to the total weight of the ink composition) of the polymer compound P-1 (weight-average molecular weight: 62,200)) as a p-type semiconductor material, and 1.5% by weight (relative to the total weight of the ink composition) of the compound N-1 as an n-type semiconductor material were mixed (p/n ratio=1/1.5), stirred at 60° C. for 12 hours, and thereafter filtered using a PTFE filter having a pore size of 5 μm to give an ink composition (I-1). The p-type semiconductor material used in the ink composition (I-1), the weight-average molecular weight of the p-type semiconductor material, and the p/n ratio are shown in the following Table 4.

### Preparation Examples 2 to 4

Ink compositions (I-2) to (I-4) were prepared using the same solvent and n-type semiconductor material as in Preparation Example 1, except that ink compositions each containing a polymer compound as a p-type semiconductor material shown in the following Table 3 were used. The p-type semiconductor materials used in the ink compositions (I-2) to (I-4), the weight-average molecular weights of the p-type semiconductor materials, and the p/n ratios are shown in the following Table 4.

TABLE 4

| | | | Weight- | |
|---|---|---|---|---|
| | | | average | |
| Preparation | Ink | Polymer | molecular | p/n |
| Example | composition | compound | weight (Mw) | Ratio |
| 1 | (I-1) | P-1 | 62,200 | 1/1.5 |
| 2 | (I-2) | P-2 | 144,000 | 1/1.5 |
| 3 | (I-3) | P-3 | 59,400 | 1/1.5 |
| 4 | (I-4) | P-4 | 110,000 | 1/1.5 |

### (Creation of Calibration Curve)

A calibration curve that demonstrates a correlation between the amount of electron spin and the area of an ESR spectrum was created using 2,2,6,6-tetramethylpiperidine 1-oxyl (TEMPO) as a reference standard. The procedure is specifically described below.

First, in 10 mL of toluene, 1.02 mg of TEMPO was dissolved to prepare a 0.65 mM TEMPO solution (standard solution 1). In a 10-mL measuring flask, 1 mL of the resulting solution was introduced, and filled up to the marking with toluene to prepare a 0.065 mM solution (standard solution 2).

In the same manner, a 0.0065 mM solution (standard solution 3) and a 0.00065 mM solution (standard solution 4) were prepared. Each of the resulting standard solutions 1 to 4 was measured for ESR to obtain an ESR spectrum, and the area of the resulting ESR spectrum was calculated. A calibration curve was created based on the calculated areas.

### Example 1

As a π-conjugated polymer, 50 mg of the polymer compound P-1 was provided. Under the air atmosphere, a cap of a glass container A (10-mL screw-capped vial) was loosened to avoid an airtight state and the polymer compound P-1 was accommodated in the container A so that the container A had an atmosphere therein to suppress increase in the electron spin concentration of the polymer compound P-1. Then, the container A and SequL AP-250 (manufactured by NISSO FINE CO., LTD.) as an oxygen absorber were placed in a re-sealable aluminum bag (aluminum Lamizip AL-10, manufactured by SEISANNIPPONSHA LTD.) as an enclosure container, and the opening of the aluminum Lamizip was sealed by heat lamination to enclose the container A and the oxygen absorber in the aluminum Lamizip, so that the oxygen concentration of the atmosphere in contact with the polymer compound P-1 became 1% or less.

The aluminum Lamizip enclosing the container A containing the polymer compound P-1 and the oxygen absorber was placed in a thermostat oven at 60° C. and 75 RH %, and allowed to stand for 2 weeks as a storage process. After a lapse of 2 weeks, the polymer compound P-1 that had undergone the storage process was measured and evaluated for external quantum efficiency (EQE) and electron spin concentration by the following methods. The methods of measurement of EQE and electron spin concentration will be described later.

Together with EQE and electron spin concentration before the storage process, the results are shown in the following Table 5. Herein, the EQE is represented as a relative value to EQE of an organic photoelectric conversion element produced using the polymer compound P-1 before the storage process.

### Example 2

The polymer compound P-2 was measured and evaluated for EQE and electron spin concentration as in Example 1, except that the polymer compound P-2 was used as a π-conjugated polymer instead of the polymer compound P-1. The results are shown in the following Table 5.

### Example 3

The polymer compound P-3 was measured and evaluated for EQE and electron spin concentration as in Example 1, except that the polymer compound P-3 was used as a π-conjugated polymer instead of the polymer compound P-1. The results are shown in the following Table 5.

### Example 4

The polymer compound P-4 was measured and evaluated for EQE and electron spin concentration as in Example 1, except that the polymer compound P-4 was used as a π-conjugated polymer instead of the polymer compound P-1. The results are shown in the following Table 5.

### Comparative Example 1

EQE and electron spin concentration were measured and evaluated as in Example 1, except that no oxygen absorber was enclosed in the aluminum Zip. The results are shown in the following Table 5.

### Comparative Example 2

EQE and electron spin concentration were measured and evaluated as in Example 2, except that no oxygen absorber was enclosed in the aluminum Zip. The results are shown in the following Table 5.

### Comparative Example 3

EQE and electron spin concentration were measured and evaluated as in Example 3, except that no oxygen absorber was enclosed in the aluminum Zip. The results are shown in the following Table 5.

### Comparative Example 4

EQE and electron spin concentration were measured and evaluated as in Example 4, except that no oxygen absorber was enclosed in the aluminum Zip. The results are shown in the following Table 5.

### (Measurement of Electron Spin Concentration)

The electron spin concentration of each of the above-described polymer compounds (p-type semiconductor materials) according to Examples 1 to 4 and Comparative Examples 1 to 4 per gram was measured by ESR measurement using an X-band ESR measurement system (manufactured by JEOL LTD.).

In an ESR tube (φ 5), 5 mg of each of the polymer compounds before storage and after the storage process was weighed out and measured for ESR. From the area of the obtained ESR spectrum, the amount of electron spin was calculated using the above-described calibration curve. The obtained amount of electron spin was divided by the weight of the p-type semiconductor material, and the resulting value was defined as the electron spin concentration per gram (spin/g) of the polymer compound.

### (Production of Organic Photoelectric Conversion Element for Measurement of EQE and Measurement of EQE)

A glass substrate carrying an ITO layer having a thickness of 150 nm that had been formed by a sputtering method was surface treated with ozone and UV to give a cathode.

A 45% by weight dispersion of zinc oxide nanoparticles (particle size: 20 to 30 nm) in isopropanol (HTD-711Z, manufactured by TAYCA CORPORATION) was diluted with 3-pentanol in an amount of 10-fold parts by weight of the dispersion to prepare an application liquid.

The resulting application liquid was applied onto the ITO layer to form a layer having a thickness of 40 nm by a spin coating method, and heated and dried at 200° C. for 10 minutes under nitrogen gas atmosphere to form an electron transport layer.

Next, ink compositions containing polymer compounds before the storage process and after the storage process as described above were applied onto the electron transport layers formed above by a spin coating method to form applied films. The resulting applied film was heated and dried for 5 minutes using a hot plate heated to 100° C. to form an active layer. The dried active layer was subject to a heat treatment (baked) in a glove box for 10 minutes using a hot plate heated to 130° C. The active layer after the heat treatment had a thickness of about 250 nm.

Then, in a resistance heating vapor deposition apparatus, a MoO₃ layer having a thickness of about 30 nm was formed on the active layer, and then a Ag layer having a thickness of about 80 nm was formed on the MoO₃ layer to give an anode.

Next, an UV curable sealing agent was applied onto the periphery of the laminated structure obtained above after the cathode formation, that is, an organic photoelectric conversion element. The element and a glass substrate were bonded together and sealed by irradiation with UV light. The resulting package of the organic photoelectric conversion element had a shape of a 1 cm×1 cm square.

The produced organic photoelectric conversion element was measured for EQE using a solar simulator (CEP-2000, manufactured by Bunkoukeiki Co., Ltd.).

TABLE 5

| | | EQE | EQE | Spin con- | Spin con- |
|---|---|---|---|---|---|
| | | (before | (after | centration | centration |
| | | storage | storage | (before | (after |
| | | process, | process, | storage | storage |
| | Polymer | relative | relative | process) | process) |
| | compound | value) | value) | (spin/g) | (spin/g) |
| Example 1 | P-1 | 1.0 | 1.0 | 6.0 × 10¹⁶ | 6.7 × 10¹⁶ |
| Example 2 | P-2 | 1.0 | 1.0 | 1.0 × 10¹⁶ | 0.68 × 10¹⁶ |
| Example 3 | P-3 | 1.0 | 0.90 | 5.8 × 10¹⁶ | 7.0 × 10¹⁶ |
| Example 4 | P-4 | 1.0 | 0.72 | 0.3 × 10¹⁶ | 0.7 × 10¹⁶ |
| Comparative | P-1 | 1.0 | 0.60 | 6.0 × 10¹⁶ | 44.3 × 10¹⁶ |
| Example 1 | | | | | |
| Comparative | P-2 | 1.0 | 0.05 | 1.0 × 10¹⁶ | 2.5 × 10¹⁶ |
| Example 2 | | | | | |
| Comparative | P-3 | 1.0 | 0.11 | 5.8 × 10¹⁶ | 13.9 × 10¹⁶ |
| Example 3 | | | | | |
| Comparative | P-4 | 1.0 | 0.12 | 0.3 × 10¹⁶ | 1.2 × 10¹⁶ |
| Example 4 | | | | | |

As apparent from Examples 1 to 4 and Comparative Examples 1 to 4, in the polymer compounds that were π-conjugated polymers that had undergone the storage process, increase in the spin concentration after the storage process was remarkably suppressed.

In addition, in organic photoelectric conversion elements produced by using p-type semiconductor materials that had undergone the storage process, decrease in EQE was remarkably prevented. The organic photoelectric conversion elements had electrical characteristics that were comparable to the electrical characteristics of an organic photoelectric conversion element produced by using a polymer compound before the storage process.

According to the present examples, it was found that a π-conjugated polymer could be stored by easy and convenient steps while increase in the electron spin concentration of the π-conjugated polymer, that is, time-dependent deterioration of the π-conjugated polymer was effectively prevented, and that even when a p-type semiconductor material after the storage process was used, a characteristic of an organic photoelectric conversion element, that is, external quantum efficiency was only affected slightly.

### Comparative Example 5

The electron spin concentrations were measured as in Example 1 (with oxygen absorber) and Comparative Example 1 (without oxygen absorber), except that the compound C-1 was used instead of the polymer compound P-1. The results are shown in the following Table 6.

TABLE 6

| | | | | Spin |
|---|---|---|---|---|
| | | | Spin | concentration |
| | | Spin | concentration | (after storage |
| | | concentration | (after storage | process) |
| | | (before | process) | (spin/g) |
| | | storage | (spin/g) with | without |
| | Com- | process) | oxygen | oxygen |
| | pound | (spin/g) | absorber | absorber |
| Comparative | C-1 | 3.5 × 10¹⁶ | 3.6 × 10¹⁶ | 3.5 × 10¹⁶ |
| Example 5 | | | | |

In the compound C-1, which was a low molecular weight compound and was not a π-conjugated polymer, no variation in spin concentration before and after the storage process was observed. That is, it is found that the method for producing an organic photoelectric conversion element, the method for storing the element, and the reagent package according to the present invention can be suitably applied to, in particular, a π-conjugated polymer.

### Example 5

In a container having an inner lid (Hi-Resist BRS-150, manufactured by KINKI YOKI CO., LTD.), 1.6 g of the polymer compound P-1 as a π-conjugated polymer was introduced under the air atmosphere. An inner lid having one perforation of 1 cm square was fitted to an opening of the body part of the container. On the inner lid, one SequL AP-250 (manufactured by NISSO FINE CO., LTD.) as an oxygen absorber was disposed, and then enclosed. The enclosure container enclosing the polymer compound P-1 and four oxygen absorbers (SequL AP-250 (manufactured by NISSO FINE CO., LTD.)) were placed in an aluminum Lamizip, and the aluminum Lamizip was sealed by heat lamination, so that the oxygen concentration of the atmosphere in contact with the polymer compound P-1 became 1% or less.

The aluminum Lamizip enclosing the container enclosing the polymer compound P-1 and the oxygen absorber and additional oxygen absorbers was placed in a thermostat oven at 60° C./75 RH %, and allowed to stand for 3 months as a storage process. After a lapse of 3 months, the polymer compound P-1 that had undergone the storage process was measured for electron spin concentration as in Example 1. Together with the electron spin concentrations before the storage process, the results are shown in the following Table 7.

### Comparative Example 6

The electron spin concentration was measured and evaluated as in Example 5, except that no oxygen absorber was enclosed in the container and the aluminum Lamizip. The results are shown in the following Table 7.

TABLE 7

| | Initial spin | Spin concentration |
|---|---|---|
| | concentration | after lapse of 3 |
| | (spin/g) | months (spin/g) |
| Example 5 | 4.6 × 10¹⁶ | 5.9 × 10¹⁶ |
| Comparative | 4.6 × 10¹⁶ | 147.5 × 10¹⁶ |
| Example 6 | | |

In Example 5 in which oxygen absorbers were disposed both in the container and in the aluminum Lamizip, as compared with Comparative Example 5 in which no oxygen absorber was disposed in the container or in the aluminum Lamizip, the a π-conjugated polymer could be stored while increase in the electron spin concentration of the π-conjugated polymer, that is, time-dependent deterioration of the π-conjugated polymer was remarkably prevented.

### DESCRIPTION OF REFERENCE SIGNS

10 Reagent package
20 Enclosure container
30 Bottle-shaped container
32 Body part
32a Opening
36 Inner lid
36a Recessed portion
36b Perforation
38 Outer lid
40 Bag-shaped container
50 Oxygen absorber
60 π-Conjugated polymer

1. A method for producing an organic photoelectric conversion element that comprises a pair of electrodes including an anode and a cathode, and an active layer that is disposed between the pair of electrodes and includes a π-conjugated polymer, the method comprising:
a storing step of storing the π-conjugated polymer in an enclosure container which has an atmosphere therein that suppresses increase in the electron spin concentration of the π-conjugated polymer; and
a step of forming the active layer using the π-conjugated polymer after storage.

2. The method for producing an organic photoelectric conversion element according to claim 1, wherein the atmosphere in the storing step is an atmosphere having an oxygen concentration of 1% or less.

3. The method for producing an organic photoelectric conversion element according to claim 1, wherein, in the storing step, an oxygen absorber is provided in the enclosure container.

4. The method for producing an organic photoelectric conversion element according to claim 1, wherein the π-conjugated polymer after storage has an electron spin concentration of 10×10¹⁶ or less per gram.

5. The method for producing an organic photoelectric conversion element according to claim 1, wherein the π-conjugated polymer after storage has a maximum absorption wavelength of 500 nm or more.

6. The method for producing an organic photoelectric conversion element according to claim 1, wherein the electron spin concentration of the π-conjugated polymer per gram after storage is less than 2.4 times as much as the electron spin concentration of the π-conjugated polymer per gram before storage.

7. The method for producing an organic photoelectric conversion element according to claim 1, further comprising:
a preparation step of preparing an application liquid containing the π-conjugated polymer after storage, wherein
the step of forming the active layer is a step of forming the active layer by applying the application liquid obtained in the preparation step.

8. A reagent package comprising:
a π-conjugated polymer for forming an active layer of an organic photoelectric conversion element;
an enclosure container enclosing the π-conjugated polymer in an airtight state, in which the enclosure container has gas barrier properties and the π-conjugated polymer can be enclosed in and taken out of the enclosure container; and
an oxygen absorber that is provided so as to come into contact with the atmosphere in the enclosure container in an airtight state, wherein the atmosphere is an atmosphere having an oxygen concentration of 1% or less.

9. The reagent package according to claim 8, wherein the it-conjugated polymer after storage has an electron spin concentration of 10×10¹⁶ or less per gram.

10. The reagent package according to claim 8, wherein the π-conjugated polymer after storage has a maximum absorption wavelength of 500 nm or more.

11. The reagent package according to claim 8, wherein the oxygen absorber contains at least one material selected from the group consisting of iron, a sugar, and a reductone.

12. The reagent package according to claim 11, wherein the material is a material containing iron.

13. The reagent package according to claim 8, wherein the enclosure container comprises:
a body part that has an opening and accommodates the π-conjugated polymer;
an inner lid that is detachably attached and fitted to an inner wall of the opening, has a recessed portion on which the oxygen absorber is capable of being mounted apart from the π-conjugated polymer, and has a perforation through which the oxygen absorber and the atmosphere in contact with the π-conjugated polymer are capable of coming into contact with each other; and
an outer lid that is detachably attached and fitted to an outer wall of the opening in a state where the inner lid is attached to make the space in the body part into an airtight state.

14. A storage method comprising a storing step of storing a π-conjugated polymer in an enclosure container which has an atmosphere therein that suppresses increase in the electron spin concentration of the π-conjugated polymer.
